(19) United States
(12) Patent Application Publication
(10) Pub. No.: US 2026/0094652 A1
(43) Pub. Date: Apr. 2, 2026

(54) NON-VOLATILE MEMORY DEVICE, STORAGE DEVICE INCLUDING THE SAME, AND OPERATING METHOD THEREOF

(71) Applicant: Samsung Electronics Co., Ltd., Suwon-si (KR)

(72) Inventors: Minji Cho, Suwon-si (KR); Se Hwan Park, Suwon-si (KR); Jin-Young Kim, Suwon-si (KR); Hyojin Ahn, Suwon-si (KR); Sangsoo Park, Suwon-si (KR); Jongmin Kim, Suwon-si (KR); Eunhyang Park, Suwon-si (KR); James Lee, Suwon-si (KR)

(21) Appl. No.: 19/324,763

(22) Filed: Sep. 10, 2025

(30) Foreign Application Priority Data
Sep. 30, 2024 (KR) 10-2024-0132926

(51) Int. Cl. G11C 16/34; G11C 16/26; G11C 16/30

(52) U.S. Cl. CPC G11C 16/3427; G11C 16/26; G11C 16/30

(57) ABSTRACT

A storage device includes a non-volatile memory (NVM) device including an adjacent word line, a selected word line, and a storage controller. The storage controller transmits a command instructing a data recovery read operation for the selected word line to the NVM device. The NVM device applies at least one group determination read voltage to the adjacent word line to classify the adjacent memory cells into an aggressor cell group. In response to receiving the command, the NVM device generates read data for the selected word line based on a read voltage set and transmits the read data to the storage controller. If the first adjacent memory cells belong to a first aggressor cell group, the first sub-read voltage set is determined based on threshold voltage distributions associated with states of the selected memory cells and on a first coupling pattern by the first aggressor cell group.

### CROSS-REFERENCE TO RELATED APPLICATION

This application claims priority to Korean Patent Application No. 10-2024-0132926, filed in the Korean Intellectual Property Office on Sep. 30, 2024, the entire contents of which are hereby incorporated by reference.

### BACKGROUND

Semiconductor memory devices may be classified into volatile memories such as dynamic random-access memories (DRAMs) and static random-access memories (SRAMs), and non-volatile memories such as electrically programmable read-only memories (EEPROMs), ferroelectric random-access memories (FRAMs), phase-change random-access memories (PRAMs), magneto-resistive random-access memories (MRAM), and flash memories. The volatile memory devices lose stored data when power is interrupted, while the non-volatile memories retain stored data even when power is interrupted. Memory cells in the non-volatile memory may undergo degradation due to various factors.

### SUMMARY

The present disclosure provides a non-volatile memory device for improving the performance of a data recovery read operation, a storage device including the same, and an operating method thereof.

A storage device may include a non-volatile memory device including an adjacent word line to which adjacent memory cells including first adjacent memory cells are connected, and a selected word line to which selected memory cells including first selected memory cells adjacent to the first adjacent memory cells are connected, and a storage controller configured to transmit a command instructing a data recovery read operation for the selected word line to the non-volatile memory device, in which the non-volatile memory device may be configured to apply at least one group determination read voltage to the adjacent word line to classify each of the adjacent memory cells into any one of aggressor cell groups, and in response to receiving the command, generate read data for the selected word line based on a read voltage set including a first sub-read voltage set for distinguishing first sub-states of the first selected memory cells and transmit the read data to the storage controller, and if the first adjacent memory cells are classified as a first aggressor cell group of the aggressor cell groups, the first sub-read voltage set may be determined based on at least some of threshold voltage distributions associated with states of the selected memory cells and on a first coupling pattern by the first aggressor cell group.

A non-volatile memory device may include a voltage generator, a control logic circuit, an adjacent word line including first adjacent memory cells and second adjacent memory cells, and a selected word line including first selected memory cells adjacent to the first adjacent memory cells and second selected memory cells adjacent to the second adjacent memory cells, in which the control logic circuit may be configured to control the voltage generator to apply at least one group determination read voltage to the adjacent word line so as to classify each of the adjacent memory cells into any one of aggressor cell groups, in response to receiving a command instructing a data recovery read operation for the selected word line, control the voltage generator to apply first sub-read voltages for distinguishing first sub-states of the first selected memory cells to the selected memory cells so as to perform a first read operation, and in response to receiving the command, control the voltage generator to apply second sub-read voltages for distinguishing second sub-states of the second selected memory cells to the selected memory cells so as to perform a second read operation, and if the first adjacent memory cells are classified as a first aggressor cell group of the aggressor cell groups, the first sub-read voltages may be determined based on at least some of threshold voltage distributions associated with states of the selected memory cells and a first coupling pattern by the first aggressor cell group, and if the second adjacent memory cells are classified as a second aggressor cell group of the aggressor cell groups, the second sub-read voltages may be determined based on at least some of the threshold voltage distributions and a second coupling pattern by the second aggressor cell group.

An operating method of a storage device including a storage controller and a non-volatile memory device may include transmitting, by the storage controller, to the non-volatile memory device, a command instructing a data recovery read operation for a selected word line to which selected memory cells including one or more selected memory cells adjacent to one or more adjacent memory cells included in an adjacent word line are connected, applying, by the non-volatile memory device, at least one group determination read voltage to the adjacent word line to classify each of the adjacent memory cells into one of aggressor cell groups, determining, by the storage device, a sub-read voltage set for distinguishing sub-states of the one or more selected memory cells, and in response to receiving the command, generating, by the non-volatile memory device, read data for the selected word line based on a read voltage set including the determined sub-read voltage set and transmitting the read data to the storage controller, and if the one or more adjacent memory cells are classified into a specific aggressor cell group of the aggressor cell groups, the sub-read voltage set may be determined based on at least some of threshold voltage distributions associated with states of the selected memory cells and a coupling pattern by the specific aggressor cell group.

According to various aspects, by calculating an offset voltage based on a coupling pattern by the adjacent memory cells classified into a specific aggressor cell group, and reflecting the offset voltage to determine a read voltage of the data recovery read operation for the selected memory cells, it is possible to improve a performance of the read operation.

According to various aspects, by calculating the offset voltage by reflecting a degradation factor associated with the selected memory cell based on at least some of the threshold voltage distributions of the selected memory cells, it is possible to further improve the performance of the read operation.

Various and beneficial advantages and effects of the present disclosure are not limited to the above description, and may be more easily understood in the process of describing specific aspects of the present disclosure.

### BRIEF DESCRIPTION OF THE DRAWINGS

The above and other objects, features and advantages of the present disclosure will become more apparent to those of ordinary skill in the art by describing in detail example aspects thereof with reference to the accompanying drawings, in which:

FIGS. 1A and 1B are block diagrams illustrating a storage system according to various aspects;

FIG. 2 is a diagram provided to explain a non-volatile memory;

FIG. 3 is a perspective view illustrating a memory block;

FIG. 4 is a circuit diagram illustrating a memory block;

FIG. 5 is a diagram provided to explain states of a plurality of memory cells according to some implementations;

FIG. 6 is a diagram provided to explain a state in which a plurality of memory cells are degraded;

FIG. 7 is a diagram provided to explain a coupling pattern and an aggressor cell group according to some implementations;

FIG. 8A is a diagram provided to explain a method for grouping a plurality of aggressor cell groups;

FIG. 8B is a diagram provided to explain a method for grouping a plurality of aggressor cell groups according to other aspects;

FIG. 8C is a diagram provided to explain a method for grouping a plurality of aggressor cell groups according to other aspects;

FIG. 9A is a diagram provided to explain sub-threshold voltage distributions generated according to a plurality of aggressor cell groups illustrated in FIG. 8A;

FIG. 9B is a diagram provided to explain sub-threshold voltage distributions generated according to a plurality of aggressor cell groups illustrated in FIG. 8B;

FIGS. 10A and 10B are diagrams provided to explain a sub-read voltage set with respect to the sub-threshold voltage distributions illustrated in FIG. 9A;

FIGS. 11A and 11B are diagrams provided to explain a read operation using the sub-read voltage sets illustrated in FIGS. 10A and 10B;

FIG. 12A is a block diagram illustrating an example of calculating a read voltage set including the sub-read voltage sets;

FIG. 12B is a diagram illustrating an example of a default voltage set and first sub-offset voltage sets;

FIG. 12C is a diagram illustrating an example of determining one sub-read voltage set;

FIGS. 13A and 13B are diagrams illustrating a process of determining an offset according to some implementations;

FIG. 14 is a flow diagram illustrating an example of generating and transmitting read data;

FIG. 15 is a block diagram schematically illustrating a process of determining second sub-offset voltage sets;

FIG. 16A is a diagram illustrating an example of a threshold voltage range in which the number of selected memory cells is counted;

FIGS. 16B and 16C are diagrams illustrating an example of a threshold voltage range in which the number of selected memory cells is counted according to various aspects;

FIGS. 17A to 17D are diagrams illustrating an example of a sub-offset table according to various aspects, provided to explain a process of determining second sub-offset voltage sets;

FIG. 18A is a diagram illustrating an example of a sub-offset table according to other aspects;

FIG. 18B is a diagram illustrating an example of second sub-offset voltage sets determined based on the sub-offset table of FIG. 18A;

FIGS. 19A and 19B are diagrams illustrating a process of determining an offset according to some implementations;

FIG. 20 is a diagram illustrating an example of calculating a shift amount of a read voltage;

FIG. 21 is a diagram illustrating an example of a sub-offset table, provided to explain a process of determining second sub-offset voltage sets in FIGS. 19A and 19B; and

FIG. 22 is a diagram conceptually illustrating an example of calculating a cell count value.

### DETAILED DESCRIPTION

Implementations of the present disclosure relate to a memory device, and specifically, to a non-volatile memory device that determines a read voltage through a data recovery read operation, a storage device including the same, and an operating method thereof.

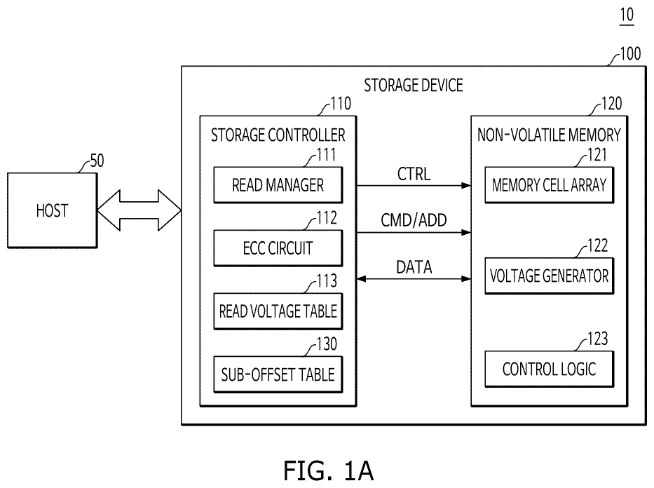

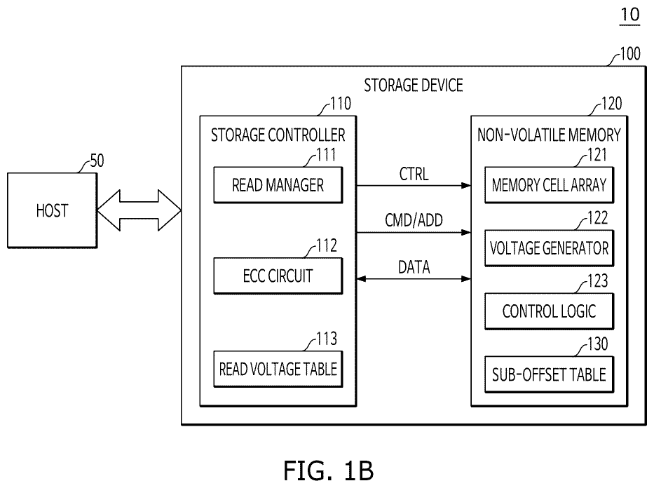

FIGS. 1A and 1B are block diagrams illustrating a storage system 10 according to various aspects.

Referring to FIGS. 1A and 1B, the storage system 10 may include a host 50 and a storage device 100.

The host 50 may communicate with the storage device 100 through an interface. For example, the interface may be implemented as NVMe, NVMe management interface (MI), or NVMe over fabric (NVMeof).

The host 50 may provide the storage device 100 with a write request to store data on the storage device 100. In addition, the host 50 may provide a logical address for identifying data and data to the storage device 100. The logical address may be included in the write request.

The host 50 may provide the storage device 100 with a read request to provide data stored in the storage device 100. In addition, the host 50 may provide a logical address for identifying the data to the storage device 100. The logical address may be included in the read request.

The storage device 100 may include a storage controller 110 and a non-volatile memory 120 which may also be referred to as a “non-volatile memory device”. The storage controller 110 and the non-volatile memory 120 may be integrated into a single semiconductor device. For example, the storage controller 110 and the non-volatile memory 120 may be integrated into a single semiconductor device and included in a memory card.

For example, the non-volatile memory 120 and storage controller 110 may be integrated into a single semiconductor device to form a PC card, a compact flash card, a smart media card, a memory stick, a multimedia card, an SD card, a universal flash memory device, etc. As another example, the storage controller 110 and the non-volatile memory 120 may be integrated into a semiconductor device to form a solid state disk/drive (SSD).

The non-volatile memory 120 may be a flash memory device including flash memory cells. However, the present disclosure is not limited thereto. Hereinafter, it is assumed that the non-volatile memory 120 is a flash memory device. The flash memory cells may be referred to as memory cells.

The non-volatile memory 120 may include a memory cell array 121. The memory cell array 121 may include a plurality of memory blocks. Each memory block may include a plurality of memory cells disposed in regions where a plurality of word lines and a plurality of bit lines intersect.

Any one of the plurality of word lines of the memory cell array 121 may be a word line (hereinafter, “selected word line”) selected as a target of the read operation, and a word line physically adjacent to the selected word line may be referred to as an adjacent word line. A plurality of memory cells included in the selected word line may be referred to as selected memory cells, and a plurality of memory cells in the adjacent word line physically adjacent to the selected memory cells may be referred to as adjacent memory cells.

A plurality of memory cells may have a plurality of threshold voltage distributions according to programmed data. For example, if a memory cell is a single level cell (hereinafter, “SLC”) that stores one bit per memory cell, the memory cells may have two threshold voltage distributions according to the programmed state. As another example, if a memory cell is a multi-level cell (hereinafter, “MLC”) that stores two bits per memory cell, the memory cells may have four threshold voltage distributions according to the programmed state. In another example, if a memory cell is a triple level cell (hereinafter, “TLC”) that stores three bits per memory cell, the memory cells may have eight threshold voltage distributions according to the program state. Likewise, if a memory cell stores four or more bits per memory cell, the memory cells may have 16 or more threshold voltage distributions according to the programmed state. One threshold voltage distribution may correspond to a specific state of a memory cell.

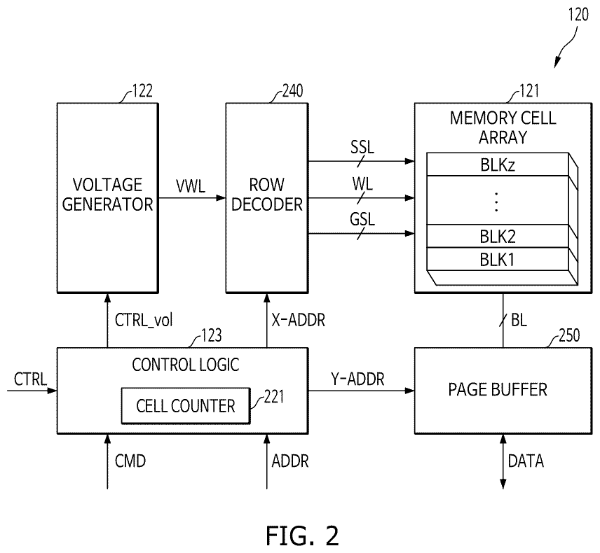

The non-volatile memory 120 may include a voltage generator 122. The voltage generator 122 may generate word line voltages and apply the word line voltages to a plurality of word lines. The voltage generator 122 will be described below with reference to FIG. 2.

The non-volatile memory 120 may include a control logic 123 also referred to as a “control logic circuit”. The control logic 123 may control the voltage generator 122 to generate word line voltages. The control logic 123 will be described below with reference to FIG. 2.

In response to a request (e.g., a write request or a read request) provided from the host 50, the storage controller 110 may read data stored in the non-volatile memory 120 or control the non-volatile memory 120 to write (or program) data to the non-volatile memory 120. Specifically, the storage controller 110 may provide a command/address CMD/ADD and a control signal CTRL to the non-volatile memory 120 to control a write operation (or a program operation), a read operation, and/or an erase operation for the non-volatile memory 120. In addition, data to be written and data to be read may be transmitted and received between the storage controller 110 and the non-volatile memory 120.

The storage controller 110 may provide a read command and an address (hereinafter, “selected address”) of a selected word line to the non-volatile memory 120. In this case, the read command may be a command instructing the reading of data stored in the selected memory cells connected to a selected word line of a plurality of word lines.

The storage controller 110 may communicate with the host 50 through various standard interfaces. For example, the storage controller 110 may include an interface circuit, and the interface circuit may provide various standard interfaces between the host 50 and the storage controller 110. The standard interface may include various interface methods such as advanced technology attachment (ATA), serial ATA (serial ATA), external SATA (e-SATA), small computer system interface (SCSI), serial attached SCSI (SAS), peripheral component interconnection (PCI), PCI express (PCI-E), IEEE 1394, universal serial bus (USB), secure digital (SD) card, multimedia card (MMC), embedded multimedia card (eMMC), universal flash storage (UFS), compact flash (CF) card interface, etc.

The storage controller 110 may include a read manager 111, an error correction code circuit (hereinafter, “ECC circuit”) 112, and a read voltage table 113.

In response to a read request provided from the host 50, the read manager 111 may control the non-volatile memory 120 to read data stored in the non-volatile memory 120. For example, in response to the read request, the read manager 111 may provide the non-volatile memory 120 with a command/address CMD/ADD instructing the reading of the data. In this case, the command instructing the reading of data may be referred to as a read command. In response to receiving the command/address CMD/ADD instructing the reading of data stored in the non-volatile memory 120, the non-volatile memory 120 may apply one or more read voltages to programmed memory cells in the non-volatile memory 120 to read the stored data.

In response to a read request, the read manager 111 may read the data stored in the non-volatile memory 120 using a default read voltage set. If the data read by the default read voltage set is not corrected by the ECC circuit 112, the read manager 111 may use a history read voltage set. If the data read by the history read voltage set is not corrected by the ECC circuit 112, the read manager 111 may use an optimal read voltage set.

The default read voltage set may include default read voltages that do not reflect the degradation of the memory cell or the memory block including the memory cells. The history read voltage set may include history read voltages previously used to read the data stored in the non-volatile memory 120. The optimal read voltage set may include optimal read voltages corresponding to points at which different threshold voltage distributions of the memory cells intersect. Additionally or alternatively, the optimal read voltage set may include a read voltage obtained as a result of the execution of a defense code. The type of the default read voltage, the history read voltage, and/or the optimal read voltage may vary according to the type of the memory cells.

The read manager 111 may manage or adjust the read voltages. For example, if the data read using the default read voltage set, the history read voltage set, and/or the optimal read voltage set is not corrected by the ECC circuit 112, the read manager 111 may adjust the read voltage used by the non-volatile memory 120. The adjusted read voltage may be included in the control signal CTRL.

In order to adjust the read voltages, the read manager 111 may initiate a data recovery read operation by transmitting a command instructing the data recovery read operation for the selected word line to the non-volatile memory 120. For example, the read manager 111 may correct the data read from the selected word line using the ECC circuit 112 and transmit a command to the non-volatile memory 120 instructing the data recovery read operation for the selected word line, in response to the occurrence of uncorrectable ECC (UECC) data.

In response to the initiation of the data recovery read operation for the selected word line, a read operation may be performed on the selected word line, thereby determining a read voltage set for generating read data. In response to receiving a command instructing the data recovery read operation, the non-volatile memory 120 may generate the read data for the selected word line using the determined read voltage set and transmit the read data to the storage controller 110. In this case, the read voltage set may include sub-read voltage sets for distinguishing sub-states of the selected memory cells. The read manager 111 may control the non-volatile memory 120 to perform an operation of reading the data stored in the selected memory cells based on the determined read voltage set.

The read voltage set for the selected word line determined as the data recovery read operation is initiated may include a plurality of sub-read voltage sets. In this case, each of the plurality of sub-read voltage sets may be used to read the data stored in the selected memory cells physically adjacent to the adjacent memory cells belonging to each of different aggressor cell groups. This choice of the plurality of sub-read voltage sets is because each of the selected memory cells in the selected word line may have a different coupling pattern according to different aggressor characteristics of the adjacent memory cells adjacent thereto.

The threshold voltage distribution of the selected memory cells may be changed not only by the coupling pattern from (or, by) the adjacent memory cells, but also by an internal factor such as degradation of the selected memory cells, etc. In other words, the threshold voltage distribution of the selected memory cells may have various distribution patterns due to external factors such as coupling patterns from (or, by) the adjacent memory cells, etc., and internal factors such as degradation of the selected memory cells, etc. Accordingly, each of the plurality of sub-read voltage sets may be determined based on at least some of the threshold voltage distributions associated with the coupling pattern from (or, by) the adjacent memory cells and states of the selected memory cells.

Specifically, each of the plurality of sub-read voltage sets may be determined using a default voltage set including default voltages and an offset voltage set including offset voltages for correcting the default voltages. In this case, the offset voltage set may include a first sub-offset voltage set including predetermined first sub-offset voltages corresponding to a specific coupling pattern, and a second sub-offset voltage set including second sub-offset voltages determined based on at least some of the threshold voltage distributions.

The read voltage table 113 may include the default read voltage set and the first sub-offset voltage set described above. Information associated with voltages in the read voltage table 113 may be transmitted to the non-volatile memory 120.

Additionally, the read voltage table 113 may store the optimal read voltage set and/or the history read voltage set described above.

A sub-offset table 130 may include the second sub-offset voltage set described above. Referring to FIGS. 1A and 1B, the sub-offset table 130 may be stored in the storage controller 110 or the non-volatile memory 120.

A read pass may be a result of a read operation corresponding to a situation in which the read data does not include an error (or the read data is normal data). Alternatively, the read pass may be a result of a read operation corresponding to a situation in which the data includes an error correctable by the ECC circuit 112. A read fail may be a result of a read operation corresponding to a situation in which the read data includes an error that cannot be corrected by the ECC circuit 112.

The ECC circuit 112 may detect and correct an error of the data read by the non-volatile memory 120. For example, the ECC circuit 112 may generate an error correction code for the data to be stored in the non-volatile memory 120. The generated error correction code may be stored in the non-volatile memory 120 together with the data. The ECC circuit 112 may detect and correct an error of the data read by the non-volatile memory 120 based on the stored error correction code. For example, the ECC circuit 112 may have a predetermined error correction capability. Data including error bits (or fail bits) exceeding the error correction capability of the ECC circuit 112 may be referred to as UECC data. The UECC data may occur if a read operation performed using each of the default read voltage set, the history read voltage set, and/or the optimal read voltage set fails.

FIG. 2 is a diagram provided to explain a non-volatile memory.

Referring to FIG. 2, the non-volatile memory 120 may include the memory cell array 121, the voltage generator 122, the control logic 123, a row decoder 240, and a page buffer circuit 250. In another aspect, the non-volatile memory 120 may further include a data input/output circuit or an input/output interface.

The memory cell array 121 may include a plurality of memory cells and may be connected to word lines WL, string select lines SSL, ground select lines GSL, and a plurality of bit lines BL. Specifically, the memory cell array 121 may be connected to the row decoder 240 through the word lines WL, the string select lines SSL, and the ground select lines GSL, and may be connected to the page buffer circuit 250 through the plurality of bit lines BL.

The memory cell array 121 may include a plurality of memory blocks BLK1 to BLKz. For example, each of the plurality of memory blocks BLK1 to BLKz may have a three-dimensional structure (or a vertical structure). Specifically, each memory block may include structures extending along first to third directions. For example, each memory block may include a plurality of NAND strings extending in the third direction. In this case, the plurality of NAND strings may be spaced apart from each other by a specific distance along the first and second directions. The plurality of memory blocks BLK1 to BLKz may be selected by the row decoder 240. For example, the row decoder 240 may select, from among the plurality of memory blocks BLK1 to BLKz, a memory block that corresponds to a block address.

Each of the memory cells included in the memory cell array 121 may store at least one bit. For example, the memory cell may be an SLC that stores 1-bit data. As another example, the memory cell may be an MLC that stores 2-bit data. As yet another example, the memory cell may be a TLC that stores 3-bit data. As yet another example, the memory cell may be a quad-level cell (or a quadruple-level cell (hereinafter, “QLC”) that stores 4-bit data. However, the present disclosure is not limited thereto.

The plurality of memory blocks BLK1 to BLKz may include at least one of a single-level cell block including SLCs, a multi-level cell block including MLCs, a triple-level cell block including TLCs, or a quad-level cell block including QLCs. For example, some of the plurality of memory blocks BLK1 to BLKz included in the memory cell array 121 may be single-level cell blocks, and other memory blocks may be multi-level cell blocks or triple-level cell blocks.

If an erase voltage is applied to the memory cell array 121, a plurality of memory cells may be in an erased state, and if a program voltage is applied to the memory cell array 121, a plurality of memory cells may be in a program state. In this case, each of the memory cells may enter an erase state or at least one program state classified according to a threshold voltage. That is, the states of the memory cell may include an erase state and at least one program state, and a specific state of each memory cell may be the erased state or a specific programmed state.

The control logic 123 may control the overall operations in the non-volatile memory 120. For example, the control logic 123 may output various control signals for writing or reading data to or from the memory cell array 121 based on the command CMD, the address ADDR, and the control signal CTRL.

The various control signals output from the control logic 123 may be provided to the voltage generator 122, the row decoder 240, and the page buffer circuit 250. For example, the control logic 123 may provide a voltage control signal CTRL_vol to the voltage generator 122.

The control logic 123 may control the voltage generator 122 to apply at least one group determination read voltage to the adjacent word line that is adjacent to the selected word line, so as to classify each of the adjacent memory cells into any one of the aggressor cell groups. In addition, the control logic 123 may control the voltage generator 122 to apply sub-read voltages for distinguishing sub-states of some of the selected memory cells to the selected memory cells, thereby performing a read operation.

In some implementations, the control logic 123 may further include a cell counter 221. The cell counter 221 may count, from data sensed by the page buffer circuit 250, the number of memory cells corresponding to a specific threshold voltage or a specific threshold voltage range. The cell counter 221 may generate a memory cell count value indicating the number of memory cells. The counted memory cells may be referred to as off cells. In another aspect, the counted cells may be referred to as on-cells. Counting the number of memory cells corresponding to the specific threshold voltage range may be performed through two read operations each corresponding to threshold voltages corresponding to the boundary values of the threshold voltage range or through a single pre-charge double sensing (SPDS) operation, but the present disclosure is not limited thereto.

The voltage generator 122 may be connected to the memory cell array 121 through a plurality of word lines WL. The voltage generator 122 may generate various types of voltages for performing a program operation, a read operation, and/or an erase operation on the memory cell array 121 based on the voltage control signal CTRL_vol. The voltage generator 122 may generate word line voltages VWL, for example, a program voltage, a verification voltage, a read voltage, an erase voltage, etc.

The program voltage, the verification voltage, the read voltage, the erase voltage, etc. generated by the voltage generator 122 may be provided to a selected word line of the plurality of word lines WL. The selected word line may be at least one word line selected by a row address X-ADDR.

During the erase operation, the voltage generator 122 may apply an erase voltage to a well and/or a common source line of a memory block. In addition, based on the erase address, the voltage generator 122 may apply an erase permission voltage (e.g., ground voltage) to all word lines WL of the memory block or to word lines corresponding to some sub-blocks. During the erase verification operation, the voltage generator 122 may apply an erase verification voltage to all the word lines WL of one memory block, or apply an erase verification voltage on a per-word-line basis.

During the program operation, the voltage generator 122 may apply a program voltage to a selected word line of the plurality of word lines WL and apply a program pass voltage to the unselected word lines of the plurality of word lines WL. In addition, during the program verification operation, the voltage generator 122 may apply a program verification voltage to the selected word line and apply a verification pass voltage to the unselected word lines.

During the normal read operation, the voltage generator 122 may apply a read voltage to the selected word line and apply a read pass voltage to the unselected word lines.

During the data recovery read operation, the voltage generator 122 may apply a read pass voltage to the selected word line and apply a read voltage to at least one word line adjacent to the selected word line. Alternatively, the voltage generator 122 may apply a read voltage to the selected word line and apply a read voltage to at least one word line adjacent to the selected word line.

In response to the row address X-ADDR received from the control logic 123, the row decoder 240 may select a specific word line from among the word lines WL. Specifically, during the program operation, the row decoder 240 may provide a program voltage to the selected word line. In addition, in response to the row address X-ADDR received from the control logic 123, the row decoder 240 may select some of the string select lines SSL or some of the ground select lines GSL.

The page buffer circuit 250 may be connected to the memory cell array 121 through a plurality of bit lines BL. In response to a column address Y-ADDR received from the control logic 123, the page buffer circuit 250 may select some of the plurality of bit lines BL. During a verification operation (e.g., an erase verification operation or a program verification operation) or a read operation, the page buffer circuit 250 may operate as a sense amplifier to sense, through a selected bit line, data stored in a selected memory cell. Meanwhile, during a program operation, the page buffer circuit 250 may operate as a write driver to input data to be stored in the memory cell array 121. The page buffer circuit 250 may include a plurality of page buffers. In this case, each of the page buffers may be connected to at least one bit line.

The page buffer circuit 250 may store data read from the memory cell array 121 or may store data to be stored in the memory cell array 121.

The page buffer circuit 250 may include a plurality of page buffers connected to a plurality of bit lines BL, respectively. The plurality of page buffers may be disposed corresponding to each of the bit lines, and each of the page buffers may include a plurality of latches. The page buffer circuit 250 may be defined as including a page buffer connected to each of the bit lines. However, in some implementations, terms may be defined differently, and for example, one page buffer may be provided to correspond to a plurality of bit lines BL, and the page buffer unit may be defined as a unit of a component arranged to correspond to each of the bit lines BL.

A control logic 123, a voltage generator 122, the row decoder 240, and the page buffer circuit 250 may be included in a peripheral circuit.

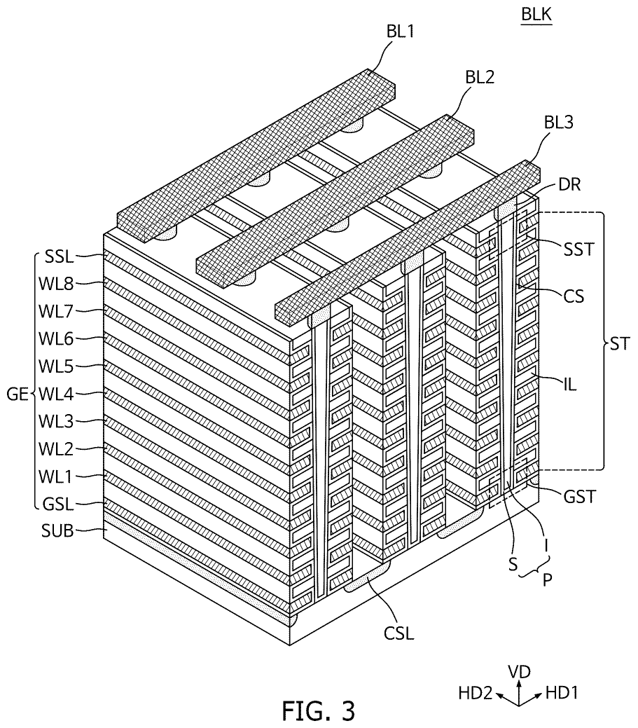

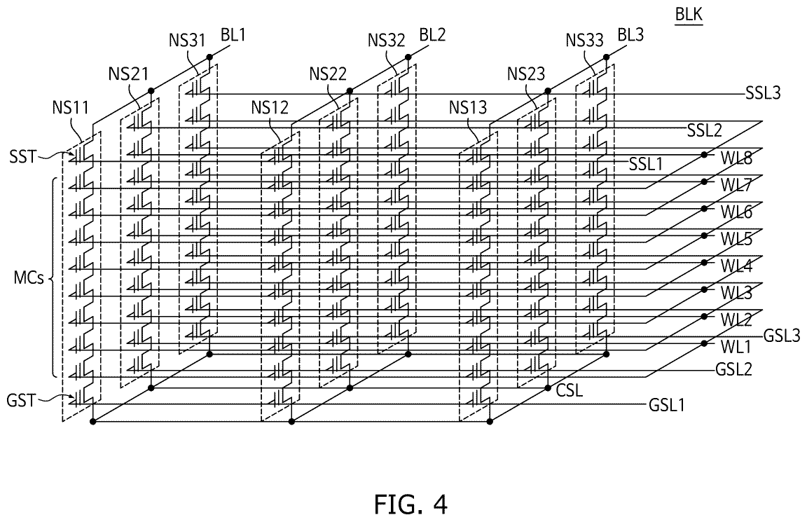

FIG. 3 is a perspective view illustrating a memory block, and FIG. 4 is a circuit diagram illustrating a memory block.

Referring to FIG. 3, a memory block BLK may include a stack ST that extends above a substrate SUB in a vertical direction VD. For example, the memory block BLK may include a single stack ST between the substrate SUB and bit lines BL1 to BL3. Common source lines CSL may be disposed on the substrate SUB, and on a region of the substrate SUB between two adjacent common source lines CSL, insulating films IL extending in a second horizontal direction HD2 may be sequentially provided in the vertical direction VD, and the insulating films IL may be spaced apart from each other by a specific distance in the vertical direction VD. Pillars P formed through the insulating films IL in the vertical direction VD are provided on the region of the substrate SUB between two adjacent common source lines CSL. The pillars may be referred to as channel holes. The pillars P may be formed in a cup shape (or in a cylindrical shape with a closed bottom) that extends in the vertical direction VD. A surface layer S of each of the pillars P may include a silicon material having a first type, and may serve as a channel region. Meanwhile, an inner layer I of each of the pillars P may include an insulating material such as silicon oxide or an air gap.

In the region between two adjacent common source lines CSL, a charge storage layer CS may be provided along exposed surfaces of the insulating films IL, the pillars P, and the substrate SUB. The charge storage layer CS may include a gate insulating layer, a charge trap layer, and a blocking insulating layer. For example, the charge storage layer CS may have an oxide-nitride-oxide (ONO) structure. In addition, gate electrodes GE such as select lines GSL and SSL and word lines WL1 to WL8 may be provided on the exposed surface of the charge storage layer CS in the region between the two adjacent common source lines CSL. Drains DR may be provided on each of the plurality of pillars P. The bit lines BL1 to BL3 extending in the first horizontal direction HD1 and spaced apart from one another by a specific distance in the second horizontal direction HD2 are provided on the drains DR.

Referring to FIG. 4, the memory block BLK may include NAND strings NS11 to NS33, and each (e.g., NS11) of the NAND strings NS11 to NS33 may include a string select transistor SST, a plurality of memory cells MC, and a ground select transistor GST connected in series. The transistors SST and GST and the memory cells MC included in each of the NAND strings may form a vertically stacked structure on the substrate.

The bit lines BL1 to BL3 may extend in a first direction, and the word lines WL1 to WL8 may extend in a second direction. The NAND strings NS11, NS21, and NS31 may be positioned between the first bit line BL1 and the common source line CSL, the NAND strings NS12, NS22, and NS32 may be positioned between the second bit line BL2 and the common source line CSL, and the NAND strings NS13, NS23, and NS33 may be positioned between the third bit line BL3 and the common source line CSL.

The string select transistor SST may be connected to corresponding string select lines SSL1 to SSL3. The memory cells MC may be connected to the corresponding word lines WL1 to WL8, respectively. The ground select transistor GST may be connected to corresponding ground select lines GSL1 to GSL3. The string select transistor SST may be connected to a corresponding bit line, and the ground select transistor GST may be connected to the common source line CSL. The number of NAND strings, the number of word lines, the number of bit lines, the number of ground select lines, and the number of string select lines may be variously changed according to aspects.

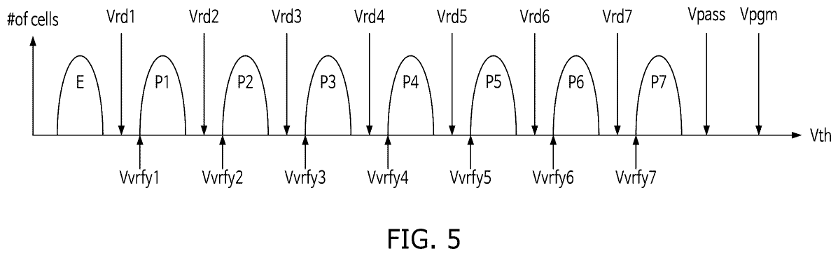

FIG. 5 is a diagram provided to explain states of a plurality of memory cells according to some implementations.

Referring to FIG. 5, the states E and P1 to P7 of the TLC are illustrated. The aspect illustrated in FIG. 5 is based on the TLC, but the present disclosure is not limited thereto, and some of the aspects described below may also be applicable to an SLC having two states (e.g., E and P1), an MLC having four states (e.g., E, P1 to P3), a QLC having 16 states (e.g., E, P1 to P15), etc. In the aspects described below, it is assumed that the memory cell is a TLC.

In FIG. 5, a horizontal axis represents a threshold voltage Vth of a memory cell, and a vertical axis represents the number of memory cells (#of cells) or a memory cell count value corresponding to the threshold voltage Vth.

The TLC may have any one of the eight states E and P1 to P7. For example, an erased TLC may have an erase state E. As another example, a programmed TLC may have one of the seven program states P1 to P7.

During the program operation, a pass voltage Vpass may be applied to all of the word lines WL, and a program voltage Vpgm may be applied to the selected word line. The program execution result (or verification) for the states E, P1 to P7 of the TLC may be distinguished by sequentially applying the first to seventh program verification voltages Vvrfy1 to Vvrfy7 to the selected word line.

The pass voltage Vpass may be a voltage sufficient to turn on the memory cell. For example, the pass voltage Vpass during a program operation may be a program pass voltage.

As illustrated in FIG. 5, the TLC may be programmed such that the areas of threshold voltage distributions corresponding to each of the states E and P1 to P7 of the TLC are equal to one another.

In another aspect, the TLC may be programmed such that the areas of threshold voltage distributions corresponding to at least one state of the TLC are formed differently from the areas of threshold voltage distributions corresponding to the remaining states. For example, TLC may be programmed such that the areas of the threshold voltage distributions corresponding to some of the states E, P1 to P5 of the TLC are the same as each other, the areas of the sixth program threshold voltage distributions are larger than the areas of the threshold voltage distributions corresponding to some of the states E and P1 to P5 of the TLC, and the areas of the threshold voltage distributions corresponding to the seventh program state P7 are smaller than the areas of the threshold voltage distributions corresponding to some of the states E and P1 to P5 of the TLC.

The area of the threshold voltage distribution corresponding to the specific state may be referred to as the area of the specific state. In addition, the area of the specific threshold voltage range in the threshold voltage distribution corresponding to a specific state and the number of memory cells within the threshold voltage range may be used interchangeably as referring to the same concept.

During the read operation, the states E, P1 to P7 of the TLC may be distinguished by applying first to seventh read voltages Vrd1 to Vrd7 to the selected word line and applying the pass voltage Vpass to the unselected word line. In this case, the first to seventh read voltages Vrd1 to Vrd7 may be referred to as default read voltages, and the first to seventh read voltages Vrd1 to Vrd7 may be included in the default read voltage set. The pass voltage Vpass may be a read pass voltage, for example.

The first read voltage Vrd1 may have a voltage level between the erase state E and the first program state P1. The second read voltage Vrd2 may have a voltage level between the first program state P1 and the second program state P2. In this manner, an i-th read voltage (where, i is an integer of 3 or more) may have a voltage level between an i−1-th program state and an i-th program state.

When the first read voltage Vrd1 is applied to the selected word line, a memory cell in the erase state E may be the on-cell, and memory cells in any one of the first to seventh program states P1 to P7 may be the off cells. When the second read voltage Vrd2 is applied to the selected word line, a memory cell in the erase state E or the first program state P1 may be the on-cell, and a memory cell in any one of the second to seventh program states P2 to P7 may be the off cell. In this manner, when the i-th read voltage (where, i is an integer of 3 or more) is applied to the selected word line, a memory cell in the erase state E or i−1-th program state may be the on-cell, and a memory cell in any one of the i-th to j-th program states (where, j is an integer of i or more) may be the off cell.

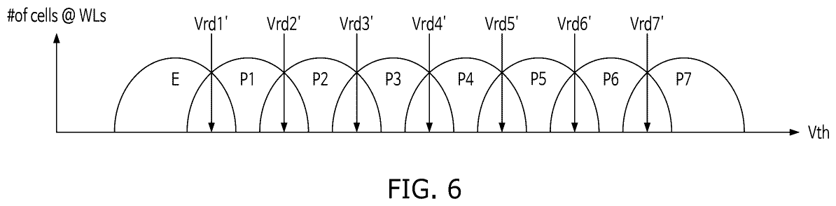

FIG. 6 is a diagram provided to explain a state in which a plurality of memory cells are degraded.

Referring to FIG. 6, the threshold voltage distributions of a plurality of memory cells may undergo degradation by various factors. The various factors may include, for example, charge leakage, read disturbance, program disturbance, coupling between adjacent memory cells, temperature change, voltage change, the degradation of memory cells due to repeated program and erase operations, etc. In particular, the threshold voltage distributions may be distorted, widened, and shifted by the coupling between adjacent memory cells (or word line interference). In addition, during a retention period, a degree of charge loss of the selected memory cells due to the influence of states of adjacent memory cells may vary, which may further increase a degree to which the threshold voltage distribution of each of the selected memory cells widens.

According to the degree of degradation of the threshold voltage distributions, a read operation performed by using existing read voltages (or default read voltage set) (e.g., the first to seventh read voltages Vrd1 to Vrd7 illustrated in FIG. 5) may result in a read fail.

Accordingly, a read operation may be performed again by using first to seventh optimal read voltages Vrd1′ to Vrd7′ as illustrated in FIG. 6.

Meanwhile, if the degree of degradation of the threshold voltage distributions is too high, it may be difficult to distinguish the states E and P1 to P7 of the TLC even with the first to seventh optimal read voltages Vrd1′ to Vrd7′. Thus, it may be necessary to calculate subdivided read voltages by classifying the coupling patterns of the selected memory cells connected to the selected word line according to the state of adjacent memory cells connected to at least one adjacent word line that is physically adjacent to the selected word line.

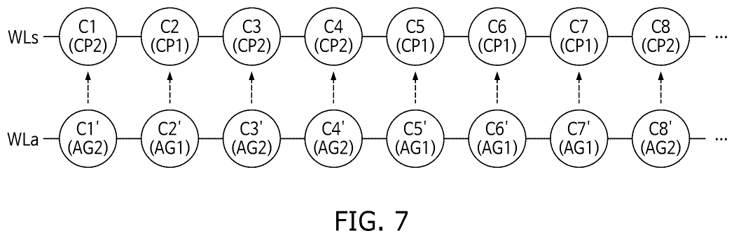

FIG. 7 is a diagram provided to explain a coupling pattern and an aggressor cell group according to some implementations.

Referring to FIG. 7, a selected word line WLs may include a plurality of selected memory cells C1 to C8. An adjacent word line WLa may include a plurality of adjacent memory cells C1′ to C8′. While FIG. 7 illustrates an example in which the number of selected memory cells C1 to C8 is 8 and the number of adjacent memory cells C1′ to C8′ is 8, the present disclosure is not limited to those illustrated in FIG. 7.

In some implementations, a single word line may be the adjacent word line WLa. For example, with reference to FIG. 3, if the selected word line WLs is an uppermost word line such as the eighth word line WL8 illustrated in FIG. 3, the adjacent word line WLa may be the seventh word line WL7. In another example, with reference to FIG. 3, if the selected word line WLs is a lowermost word line such as the first word line WL1 as illustrated in FIG. 3, the adjacent word line WLa may be the second word line WL2. For example, with reference to FIGS. 6 and 7, if the selected word line WLs is an n-th word line WLn or the first word line WL1, the adjacent word line WLa may be an n−1-th word line which is physically adjacent to the n-th word line WLn, or a second word line which is physically adjacent to the first word line WL1. In another example, with reference to FIGS. 6 and 7, if the selected word line WLs is a m+1-th word line WLm+1 or a m−1-th word line WLm−1, the adjacent word line WLa may be an m+2-th word line WLm+2 which is physically adjacent to the m+1-th word line WLm+1, or an m−2-th word line WLm−2 which is physically adjacent to the m−1-th word line WLm−1. In this case, since data may not be stored in dummy memory cells DMCm connected to a dummy word line DWLm, the dummy memory cells DMCm may not have coupling effects on the memory cells adjacent to the dummy memory cells DMCm. Accordingly, the dummy word line DWLm may not be included in the adjacent word line WLa.

The plurality of selected memory cells C1 to C8 may be adjacent to the plurality of adjacent memory cells C1′ to C8′, respectively. For example, a selected memory cell Ck (where, k is a natural number of 1 or more) may be adjacent to an adjacent memory cell Ck′.

Each selected memory cell may be coupled to an adjacent memory cell adjacent thereto, and degradation may occur in each selected memory cell.

In some implementations, each of the plurality of selected memory cells C1 to C8 may have a coupling pattern according to an aggressor cell group of each of the plurality of adjacent memory cells C1′ to C8′. For example, it is assumed that the aggressor cell group includes a first aggressor cell group AG1 and a second aggressor cell group AG2. The first selected memory cells C2, C5, C6, and C7 adjacent to the first adjacent memory cells C2′, C5′, C6′, and C7′ included in the first aggressor cell group AG1 may have a first coupling pattern CP1. The second selected memory cells C1, C3, C4, and C8 adjacent to the second adjacent memory cells C1′, C3′, C4′, and C8′ included in the second aggressor cell group AG2 may have a second coupling pattern CP2. However, the present disclosure is not limited thereto.

A method for grouping a plurality of aggressor cell groups for the plurality of adjacent memory cells C1′ to C8′ will be described below.

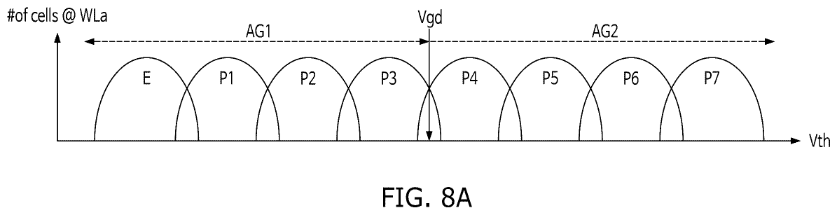

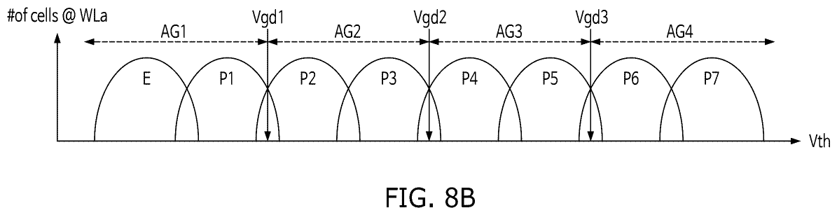

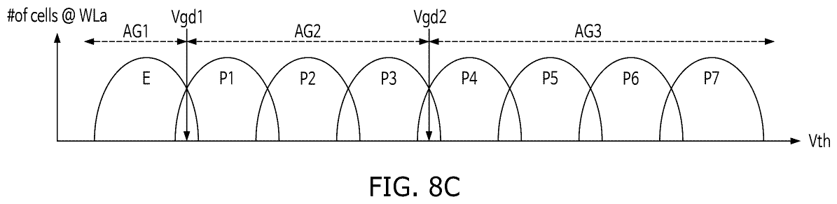

FIG. 8A is a diagram provided to explain a method for grouping a plurality of aggressor cell groups.

Referring to FIG. 8A, a horizontal axis in FIG. 8A represents a threshold voltage Vth of a memory cell, and a vertical axis represents the number (#of cells @ WLa) or the memory cell count value of the adjacent memory cells connected to the adjacent word line WLa.

The non-volatile memory device may compare a group determination read voltage Vgd with a threshold voltage of each of the adjacent memory cells connected to the adjacent word line WLa, and classify (or group) each of the adjacent memory cells into two aggressor cell groups, for example, into the first aggressor cell group AG1 or the second aggressor cell group AG2. In an example, the first aggressor cell group AG1 and the second aggressor cell group AG2, which are distinguished from each other by one group determination read voltage Vgd, may be referred to as a non-aggressor cell group and an aggressor cell group, respectively.

The first aggressor cell group AG1 may include a memory cell having a threshold voltage lower than one group determination read voltage Vgd. The second aggressor cell group AG2 may include a memory cell having a threshold voltage higher than one group determination read voltage Vgd. For example, with reference to FIGS. 7 and 8A, in response to determining that the first adjacent memory cells C2′, C5′, C6′, and C7′ have a threshold voltage lower than one group determination read voltage Vgd, the first adjacent memory cells C2′, C5′, C6′, and C7′ may be classified as the first aggressor cell group AG1. In another example, with reference to FIGS. 7 and 8A, in response to determining that the second adjacent memory cells C1′, C3′, C4′, and C8′ have a threshold voltage higher than one group determination read voltage Vgd, the second adjacent memory cells C1′, C3′, C4′, and C8′ may be classified as the second aggressor cell group AG2.

The coupling pattern of each of the selected memory cells C1 to C8 may be determined according to the aggressor cell group to which an adjacent memory cell corresponding to the coupling pattern belongs.

FIG. 8B is a diagram provided to explain a method for grouping a plurality of aggressor cell groups according to other aspects.

Referring to FIG. 8B, each of the adjacent memory cells connected to the adjacent word line WLa may be grouped into one of four aggressor cell groups, for example, first to fourth aggressor cell groups AG1 to AG4, by three group determination read voltages Vgd1, Vgd2, and Vgd3. The first aggressor cell group AG1 may be referred to as a non-aggressor cell group.

The first aggressor cell group AG1 may include a memory cell having a threshold voltage lower than the first group determination read voltage Vgd1. The second aggressor cell group AG2 may include a memory cell having a threshold voltage higher than the first group determination read voltage Vgd1 and lower than the second group determination read voltage Vgd2. The third aggressor cell group AG3 may include a memory cell having a threshold voltage higher than the second group determination read voltage Vgd2 and lower than the third group determination read voltage Vgd3. The fourth aggressor cell group AG4 may include a memory cell having a threshold voltage higher than the third group determination read voltage Vgd3.

As illustrated in FIG. 8B, the three group determination read voltages Vgd1, Vgd2, and Vgd3 may be set such that the number of states belonging to each aggressor cell group is equal. However, the present disclosure is not limited thereto. For example, the group determination read voltages (e.g., Vgd1, Vgd2, and/or Vgd3) may be set such that at least two aggressors have different numbers of states (see e.g., FIG. 8C showing that AG1 has one state and AG2 has three states).

If the number of types of aggressor cell groups is 4, the number of types of coupling patterns may be 4. For example, a plurality of coupling patterns may include first to fourth coupling patterns corresponding to each of the first to fourth aggressor cell groups AG1 to AG4.

Although the three group determination read voltages Vgd1, Vgd2, and Vgd3 are illustrated in FIG. 8B, the present disclosure is not limited thereto, and the storage controller 110 may generate a control signal that instructs the application of four or more group determination read voltages.

FIG. 8C is a diagram provided to explain a method for grouping a plurality of aggressor cell groups according to other aspects.

Referring to FIG. 8C, each of the adjacent memory cells connected to the adjacent word line WLa may be grouped into three aggressor cell groups, for example, the first aggressor cell group AG1, the second aggressor cell group AG2, or the third aggressor cell group AG3, by two group determination read voltages Vgd1 and Vgd2. The first aggressor cell group AG1 may be referred to as a non-aggressor cell group.

The storage controller 110 may group, for each of the adjacent memory cells connected to one adjacent word line WLa, the adjacent memory cells having a threshold voltage that is included in the same level section as one of the level sections classified by the levels of the two group determination read voltages Vgd1 and Vgd2.

The first aggressor cell group AG1 may include a memory cell having a threshold voltage lower than the first group determination read voltage Vgd1. The second aggressor cell group AG2 may include a memory cell having a threshold voltage higher than the first group determination read voltage Vgd1 and lower than the second group determination read voltage Vgd2. The third aggressor cell group AG3 may include a memory cell having a threshold voltage higher than the second group determination read voltage Vgd2.

A voltage level of each of the two group determination read voltages Vgd1 and Vgd2 may be set such that the number of states belonging to each aggressor cell group is not the same as each other. Referring to FIG. 8C, for example, the first group determination read voltage Vgd1 may have a voltage level between the erase state E and the first program state P1. The second group determination read voltage Vgd2 may have a voltage level between the third program state P3 and the fourth program state P4. In this case, the erase state E may belong to the first aggressor cell group AG1, the first to third program states P1 to P3 may belong to the second aggressor cell group AG2, and the fourth to seventh program states P4 to P7 may belong to the third aggressor cell group AG3. However, the present disclosure is not limited to the above examples, and various other methods for setting voltage levels may be applicable such as the first group determination read voltage Vgd1 has a voltage level between the first program state P1 and the second program state P2, the second group determination read voltage Vgd2 has a voltage level between the third program state P3 and the fourth program state P4, etc.

Referring to FIGS. 1 and 8A to 8C, the storage controller 110 may provide a control signal CTRL and an adjacent address to the non-volatile memory 120. The adjacent address may be an address corresponding to the adjacent word line WLa. In this case, the control signal CTRL may be a signal instructing the sequential application of at least one group determination read voltage to the adjacent word line WLa. For example, in FIG. 8A, the control signal CTRL may be a signal instructing the application of the group determination read voltage Vgd to the adjacent word line WLa, in FIG. 8B, the control signal CTRL may be a signal instructing the sequential application of the three group determination read voltages Vgd1, Vgd2, and Vgd3 to the adjacent word line WLa, and in FIG. 8C, the control signal CTRL may be a signal instructing the sequential application the two group determination read voltages Vgd1 and Vgd2 to the adjacent word line WLa. The non-volatile memory 120 may compare the threshold voltage of each of the adjacent memory cells with at least one group determination read voltage to classify the adjacent memory cells into any one of the aggressor cell groups.

The storage controller 110 may classify the coupling pattern of an N-th selected memory cell corresponding to an N-th adjacent memory cell included in an N-th aggressor cell group as an N-th coupling pattern, where, N is an integer of 1 or more. For example, if there are four types of aggressor cell groups, there may be four types of coupling patterns, and the plurality of coupling patterns may include first to fourth coupling patterns corresponding to each of the first to fourth aggressor cell groups AG1, AG2, AG3, and AG4. Unlike the example described above, the adjacent memory cells may be classified into an aggressor cell group and a non-aggressor cell group, or may be classified into an aggressor cell, an intermediate-aggressor cell or a non-aggressor cell, Among the adjacent memory cells, cells programmed with a relatively high threshold voltage may have a relatively higher voltage applied to a control gate connected thereto during programming. Thus, the coupling from those cells may be greater than the coupling from the cells programmed to have a relatively low threshold voltage.

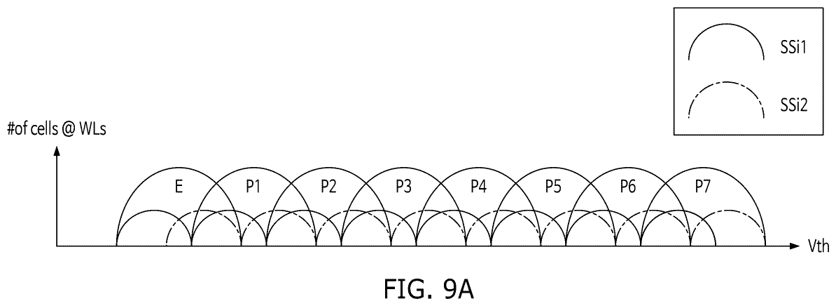

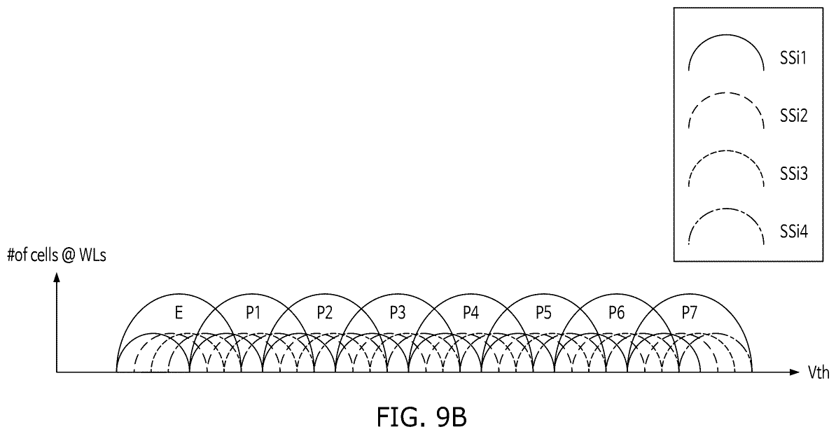

FIG. 9A is a diagram provided to explain sub-threshold voltage distributions generated according to the plurality of aggressor cell groups illustrated in FIG. 8A.

Referring to FIGS. 7, 8A, and 9A, in FIG. 9A, a horizontal axis represents a threshold voltage Vth of a memory cell, and a vertical axis represents the number (#of cells @ WLs) or the memory cell count value of the selected memory cells connected to the selected word line WLs.

The threshold voltage distributions of the selected memory cells may be classified into sub-threshold voltage distributions according to a coupling pattern of each selected memory cell. In detail, each of the states E and P1 to P7 of the selected memory cells may be subdivided into a first sub-state SSi1 corresponding to the first coupling pattern CP1 and a second sub-state SSi2 corresponding to the second coupling pattern CP2.

A sum of areas of two sub-states SSi1 and SSi2 corresponding to each state may be the same as the area of each state. For example, the sum of the areas of the two sub-states SSi1 and SSi2 corresponding to the erase state E may be the same as the area of the erase state E. The area of the first sub-state SSi1 (or the area of the second sub-state SSi2) corresponding to the erased state E may correspond to half of the area of the erased state E.

FIG. 9B is a diagram provided to explain sub-threshold voltage distributions generated according to the plurality of aggressor cell groups illustrated in FIG. 8B.

Referring to FIG. 9B, a horizontal axis in FIG. 9B represents a threshold voltage Vth of a memory cell, and a vertical axis represents the number (#of cells @ WLs) or the memory cell count value of the selected memory cells connected to the selected word line WLs.

In FIG. 9B, if the number of types of aggressor cell groups is 4, each of the states E and P1 to P7 of the selected memory cells may be subdivided into first to fourth sub-states SSi1 to SSi4 corresponding to each of the first to fourth coupling patterns. For example, the first sub-state SSi1 may correspond to the first coupling pattern, the second sub-state SSi2 may correspond to the second coupling pattern, the third sub-state SSi3 may correspond to the third coupling pattern, and the fourth sub-state SSi4 may correspond to the fourth coupling pattern.

A sum of areas of the four sub-states SSi1 to SSi4 corresponding to each state (e.g., the erase state E) may be the same as the area of each state. The area of one sub-state (e.g., the first sub-state SSi1) may correspond to ¼ of the area of the corresponding state.

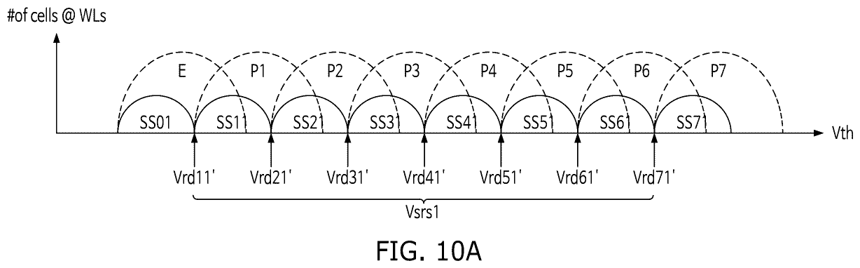

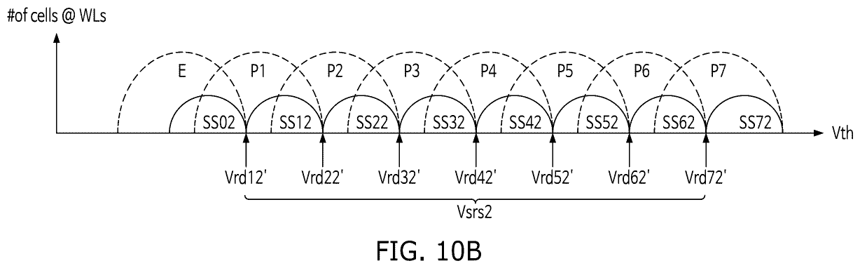

FIGS. 10A and 10B are diagrams provided to explain a sub-read voltage set with respect to the sub-threshold voltage distributions illustrated in FIG. 9A. Specifically, FIG. 10A is a diagram illustrating first sub-states SS01 to SS71 of the selected memory cells having the first coupling pattern CP1, and FIG. 10B is a diagram illustrating second sub-states SS02 to SS72 of the selected memory cells having the second coupling pattern CP2.

In FIGS. 10A and 10B, a horizontal axis represents the threshold voltage Vth of the memory cell, and a vertical axis represents the number (#of cells @ WLs) or the memory cell count value of the selected memory cells connected to the selected word line WLs.

Referring to FIG. 10A, if a first sub-read voltage set Vsrs1 including first sub-read voltages Vrd11′ to Vrd71′, which are optimal read voltages for distinguishing the first sub-states SS01 to SS71′ of the first selected memory cells, is obtained, the first sub-read voltages Vrd11′ to Vrd71′ may be applied to the selected memory cells to perform a first read operation.

Likewise, referring to FIG. 10B, if a second sub-read voltage set Vsrs2 including the second sub-read voltages Vrd12′ to Vrd72′, which are optimal read voltages for distinguishing the second sub-states SS02 to SS72′ of the second selected memory cells, is obtained, the second sub-read voltages Vrd12′ to Vrd72′ may be applied to the selected memory cells to perform a second read operation.

The first sub-read voltage set Vsrs1 and the second sub-read voltages Vrd12′ to Vrd72′ may be included in a read voltage set for generating read data for the selected word line.

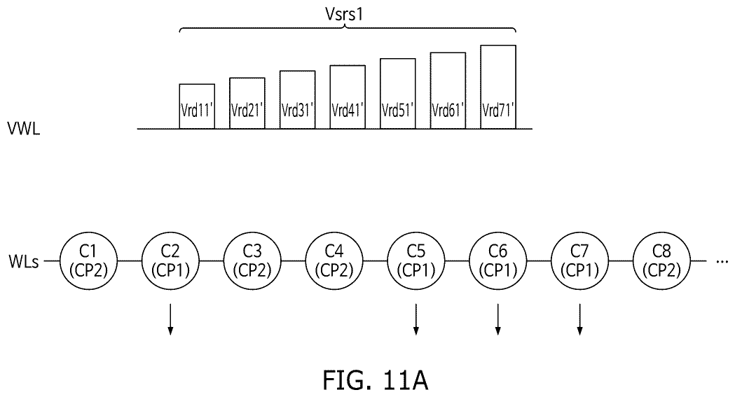

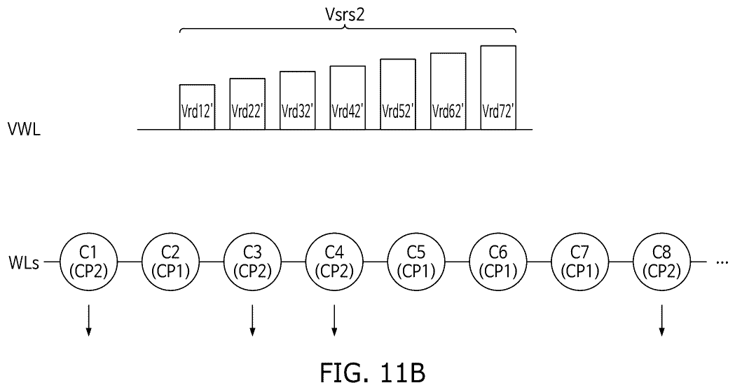

FIGS. 11A and 11B are diagrams provided to explain a read operation using the sub-read voltage sets illustrated in FIGS. 10A and 10B.

Referring to FIG. 11A, if first adjacent memory cells physically adjacent to the first selected memory cells C2, C5, C6, and C7 are classified as the first aggressor cell group AG1, based on at least some of the threshold voltage distributions associated with the states of the selected memory cells C1 to C8 and on the first coupling pattern by the first aggressor cell group AG1, the first sub-read voltage set Vsrs1 may be selected/determined as a sub-read voltage set for distinguishing the first sub-states of the first selected memory cells C2, C5, C6, and C7.

The storage controller 110 may provide the non-volatile memory 120 with a control signal instructing sequential application of the first sub-read voltages Vrd11′ to Vrd71′ to the selected word line WLs.

As the first sub-read voltages Vrd11′ to Vrd71′ corresponding to the first coupling pattern CP1 are applied to the selected word line WLs, the first read operation of reading the data from the first selected memory cells C2, C5, C6, and C7 having the first coupling pattern CP1 may be performed. In this case, data read from the second selected memory cells C1, C3, C4, and C8 not having the first coupling pattern CP1 (e.g., having the second coupling pattern CP2) may be ignored. The selected word line voltage VWL may be the first sub-read voltage set Vsrs1. In FIG. 11A, the first sub-read voltage set Vsrs1 is applied sequentially from the first sub-read voltage Vrd11′ of the lowest voltage level to the seventh sub-read voltage Vrd71′ of the highest voltage level, but the present disclosure is not limited thereto. In some implementations, the order in which the sub-read voltages Vrd11′ to Vrd71′ are applied to the selected word line WLs may be variously determined.

Referring to FIG. 11B, if second adjacent memory cells physically adjacent to the second selected memory cells C1, C3, C4, and C8 are classified as the second aggressor cell group AG2, based on at least some of the threshold voltage distributions associated with the states of the selected memory cells C1 to C8 and on the second coupling pattern by the second aggressor cell group AG2, the second sub-read voltage set Vsrs2 may be selected/determined as a sub-read voltage set for distinguishing the second sub-states of the second selected memory cells C1, C3, C4, and C8.

The storage controller 110 may provide the non-volatile memory 120 with a control signal instructing to sequentially apply the second sub-read voltages Vrd12′ to Vrd72′ to the selected word line WLs.

As the second sub-read voltages Vrd12′ to Vrd72′ corresponding to the second coupling pattern CP2 are applied to the selected word line WLs, the second read operation of reading the data from the second selected memory cells C1, C3, C4, and C8 having the second coupling pattern CP2 may be performed. In this case, data read from the first selected memory cells C2, C5, C6, and C7 not having the second coupling pattern CP2 (i.e., having the first coupling pattern CP1) may be ignored. In another aspect, the selected word line voltage VWL may be the second sub-read voltage set Vsrs2. The order in which the sub-read voltages Vrd12′ to Vrd72′ illustrated in FIG. 11B are applied to the selected word line WLs may be variously determined.

As described above, a plurality of read operations may be performed on the plurality of selected memory cells C1 to C8 having a plurality of coupling patterns CP1 and CP2 based on a plurality of sub-read voltage sets Vsrs1 and Vsrs2. A plurality of logic values may be sensed for each of the selected memory cells by the plurality of read operations performed using the plurality of sub-read voltage sets, and among these, a logic value that corresponds to an aggressor cell group to which an adjacent memory cell adjacent to the selected memory cell is classified may be determined to be the data stored in the corresponding selected memory cell. That is, according to the example described above, the read data for the selected word line WLs may include data sensed in the first selected memory cells by the first read operation and data sensed in the second selected memory cells by the second read operation. The generated read data may be transmitted to the storage controller 110. The read operation performed using sub-read voltage sets may be referred to as a data recovery read operation.

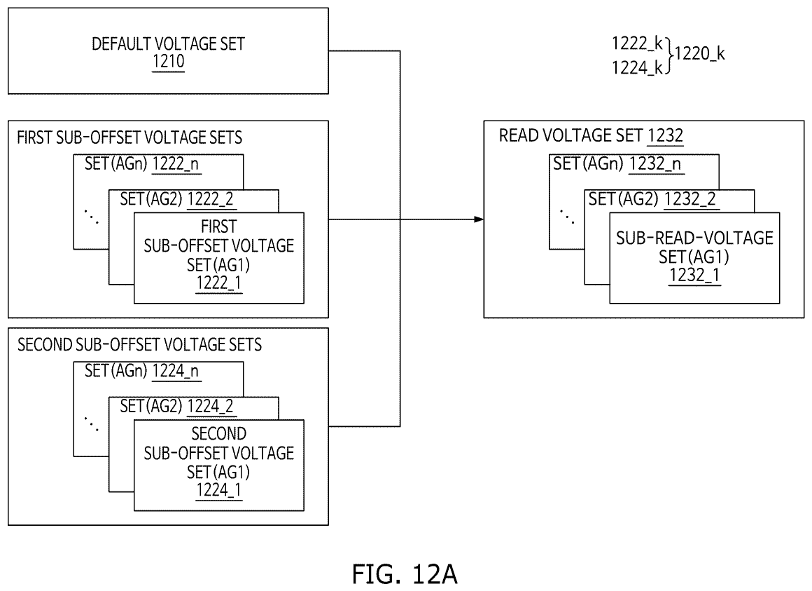

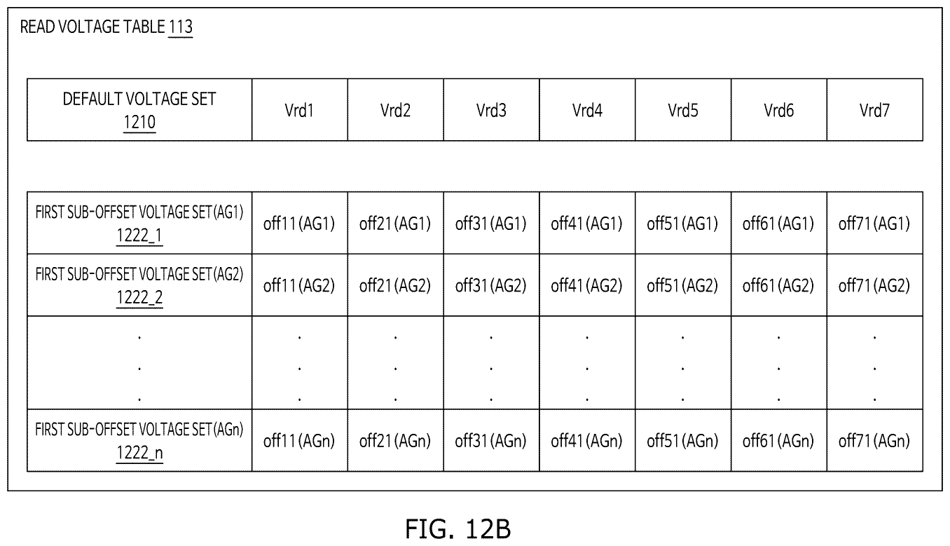

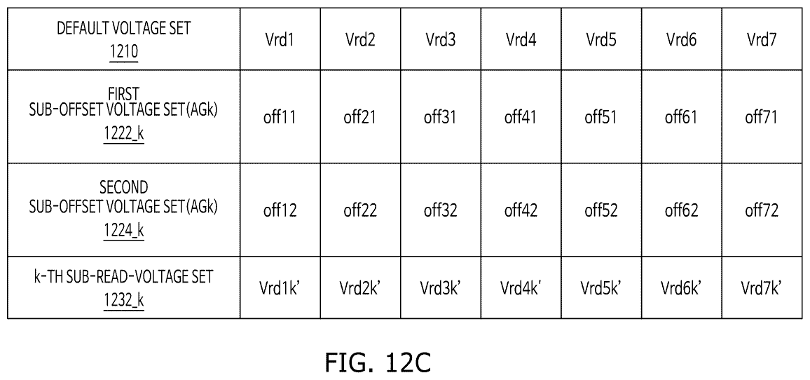

A method for calculating the plurality of sub-read voltage sets Vsrs1 and Vsrs2 will be described with reference to FIGS. 12A to 18B.

FIG. 12A is a block diagram illustrating an example of calculating a read voltage set 1232 including sub-read voltage sets 1232_1 to 1232_n, FIG. 12B is a diagram illustrating an example of a default voltage set 1210 and first sub-offset voltage sets 1222_1 to 1222_n, and FIG. 12C is a diagram illustrating an example of determining one sub-read voltage set 1232_1.

Referring to FIG. 12A, the read voltage set 1232 (or the sub-read voltage sets 1232_1 to 1232_n) may be determined by using the default voltage set 1210 including default voltages for distinguishing the states of selected memory cells and offset voltage sets 1220_1 to 1220_n including offset voltages for correcting default voltages (where, n is a natural number of 1 or more). The offset voltage sets 1220_1 to 1220_n may include the first sub-offset voltage sets 1222_1 to 1222_n and second sub-offset voltage sets 1224_1 to 1224_n.

The default read voltage set 1210 may include the default read voltages Vrd1 to Vrd7 that do not reflect the degradation of the selected memory cell or the memory block including the selected memory cells.

Each of the first sub-offset voltage sets 1222_1 to 1222_n may include first sub-offset voltages for correcting a factor caused by the adjacent memory cells with respect to the default read voltages, in consideration of the degree to which the adjacent memory cells interfere with the selected memory cells.

Each of the second sub-offset voltage sets 1224_1 to 1224_n may include second sub-offset voltages for correcting internal factors such as degradation of the selected memory cells.

Referring to FIGS. 1A, 1B, and 12B, the read voltage table 113 of the storage controller 110 may include the default read voltage set 1210 and the first sub-offset voltage sets 1222_1 to 1222_n described above.

Each of the default read voltages Vrd1 to Vrd7 of the default read voltage set 1210 may have one value independent of characteristics of adjacent memory cells.

Since the first sub-offset voltage sets 1222_1 to 1222_n are provided for correcting the factors caused by the adjacent memory cells in consideration of the degree to which the adjacent memory cells interfere with the selected memory cells, each of the first sub-offset voltage sets 1222_1 to 1222_n may have different first sub-offset voltages off11 to off71 depending on the aggressor characteristics of the adjacent memory cells. For example, first sub-offset voltages off11 (AGk) to off71 (AGk) of a first sub-offset voltage set 1222_k associated with the degree to which an adjacent memory cell classified as a k-th aggressor cell group interferes with the selected memory cells may be greater than first sub-offset voltages off11 (AGk-1) to off71 (AGk-1) of a first sub-offset voltage set 1222_k-1 associated with the degree to which an adjacent memory cell classified as a k-1th aggressor cell group interferes with the selected memory cells (where, k is a natural number from 2 to n, inclusive).

The first sub-offset voltages off11 to off71 of each of the first sub-offset voltage sets 1222_1 to 1222_n may be predetermined in consideration of the degree to which the adjacent memory cell classified as a corresponding aggressor cell group interferes with the selected memory cells. The first sub-offset voltages off11 to off71 may be the same as or different from each other.

Referring to FIG. 12C, a k-th sub-read voltage set 1232_k for distinguishing k-th sub-states of k-th selected memory cells adjacent to the k-th adjacent memory cells classified as a k-th aggressor cell group AGk may be determined based on the corresponding first sub-offset voltage set 1222_k and second sub-offset voltage set 1224_k (where, k is a natural number from 1 to n, inclusive).

For example, k-th sub-read voltages Vrd1k′ to Vrd2k′ of the k-th sub-read voltage set 1232_k may be calculated by summing each of the default read voltages Vrd1 to Vrd7 of the default read voltage set 1210, each of the first sub-offset voltages off11 to off71 of the first sub-offset voltage set 1222_k for calculating the k-th sub-read voltage set 1232_k, and each of second sub-offset voltages off12 to off72 of the second sub-offset voltage set 1224_k for calculating the k-th sub-read voltage set 1232_k. For example, the Vrd1k′ may be the sum of Vrd1, off11, and off12.

The first sub-offset voltage set 1222_k may be determined based on a k-th coupling pattern caused by the k-th aggressor cell group AGk. The first sub-offset voltage set 1222_k may include predetermined k-th sub-offset voltages corresponding to the k-th coupling pattern. That is, if specific adjacent memory cells are classified as the k-th aggressor cell group AGk of the aggressor cell groups, for the selected memory cells physically adjacent to the corresponding adjacent memory cells, the first sub-offset voltage sets 1222_k of the first sub-offset voltage sets 1222_1 to 1222_n may be determined or selected as a part of the offset voltage set.

The second sub-offset voltage set 1224_k may be determined based on at least some of the threshold voltage distributions corresponding to the states (e.g., E, P1 to P7) of the selected memory cells.

The first sub-offset voltage set 1222_k and the second sub-offset voltage set 1224_k for calculating the k-th sub-read voltage set 1232_k may be referred to as an offset voltage set 1220_k for calculating the k-th sub-read voltage set 1232_k.

Offset voltages of the offset voltage set 1220_k for calculating the k-th sub-read voltage set 1232_k may be calculated by adding each of the first sub-offset voltages off11 to off71 and each of the second sub-offset voltages off12 to off72. Alternatively, the offset voltages of the offset voltage set 1220_k may be directly calculated based on at least some of the threshold voltage distributions corresponding to the k-th coupling pattern by the k-th aggressor cell group and the states of the selected memory cells, rather than separately determining or generating the first sub-offset voltage set 1222_k and the second sub-offset voltage set 1224_k.

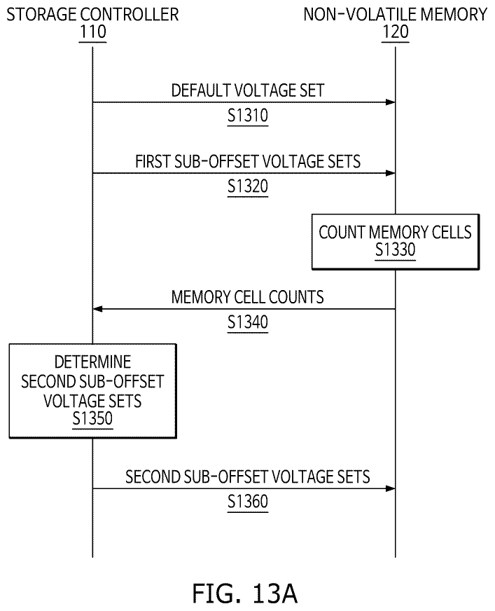

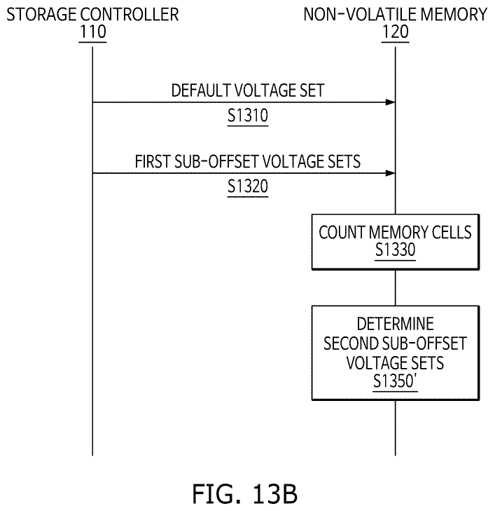

FIGS. 13A and 13B are diagrams illustrating a process of determining an offset according to some implementations.

Referring to FIGS. 13A and 13B, the storage controller 110 may transmit a default voltage set (e.g., 1210 in FIG. 12A) including default voltages for distinguishing the states of the selected memory cells to the non-volatile memory 120, at S1310. In addition, the storage controller 110 may transmit the first sub-offset voltage sets (e.g., 1222_1 to 1222_n in FIG. 12A) to the non-volatile memory 120, at S1320. In FIGS. 13A and 13B, it is illustrated that the default voltage set and the first sub-offset voltage sets are sequentially transmitted to the non-volatile memory 120 in separate steps, but the present disclosure is not limited thereto.

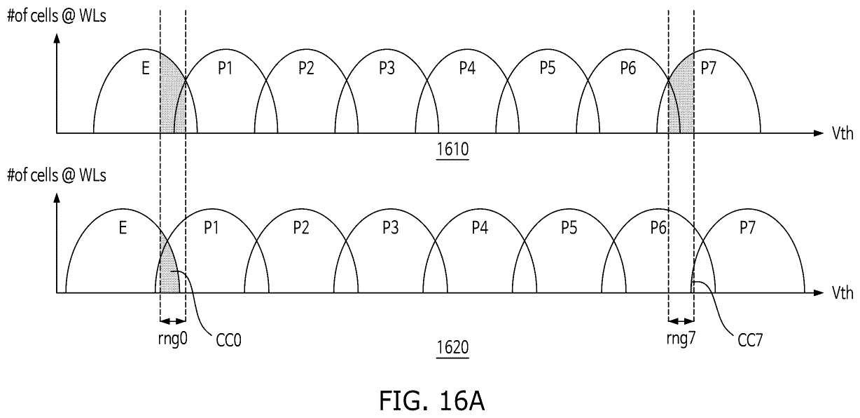

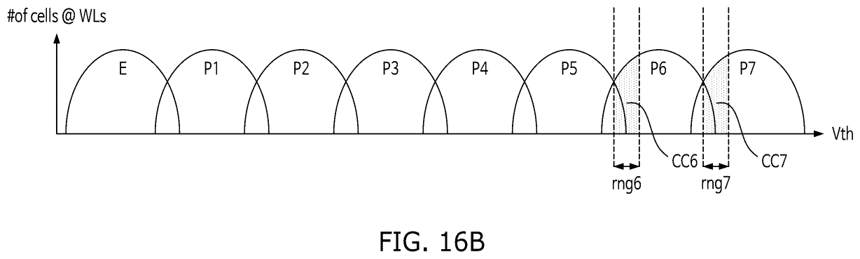

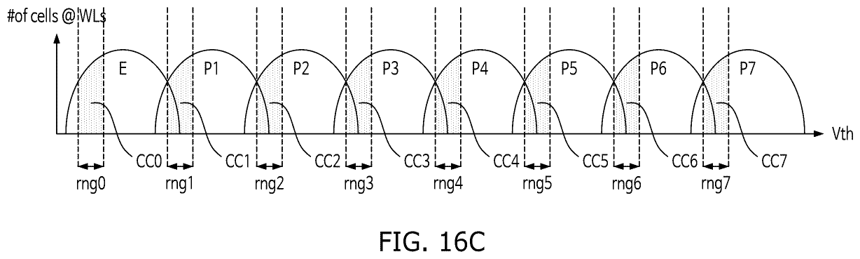

The non-volatile memory 120 may count the number of selected memory cells that fall within a predetermined threshold voltage range in each of one or more threshold voltage distributions of the selected memory cells, at S1330. This will be described in detail below with reference to FIGS. 16A to 16C.

Referring to FIGS. 1A and 13A, the non-volatile memory 120 may transmit the number of selected memory cells that fall within a predetermined threshold voltage range in each of one or more threshold voltage distributions to the storage controller 110, at S1340.

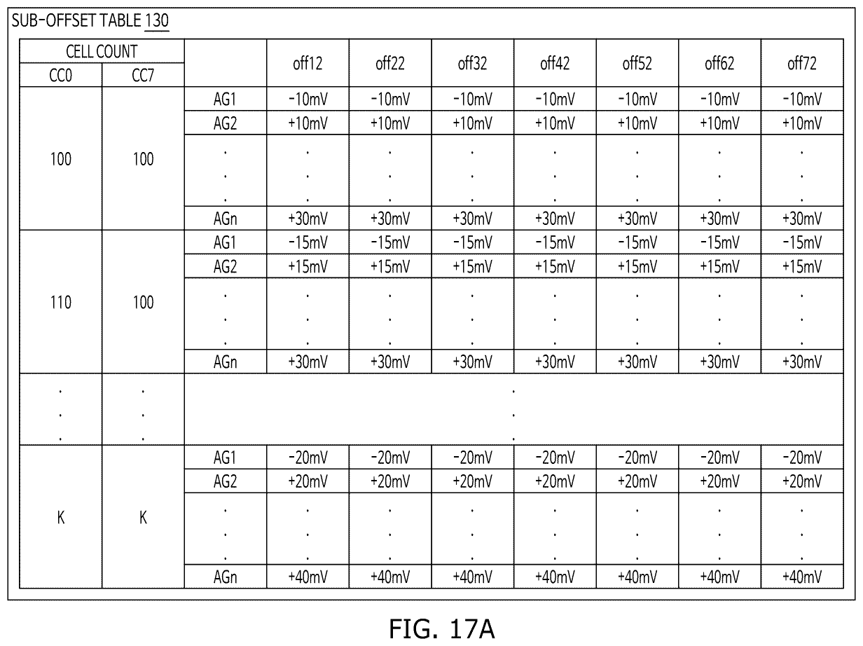

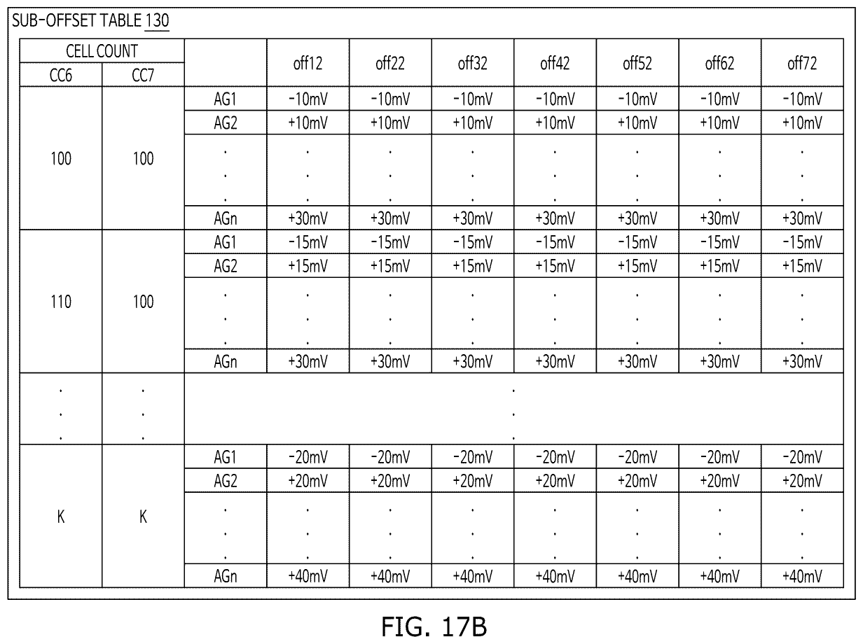

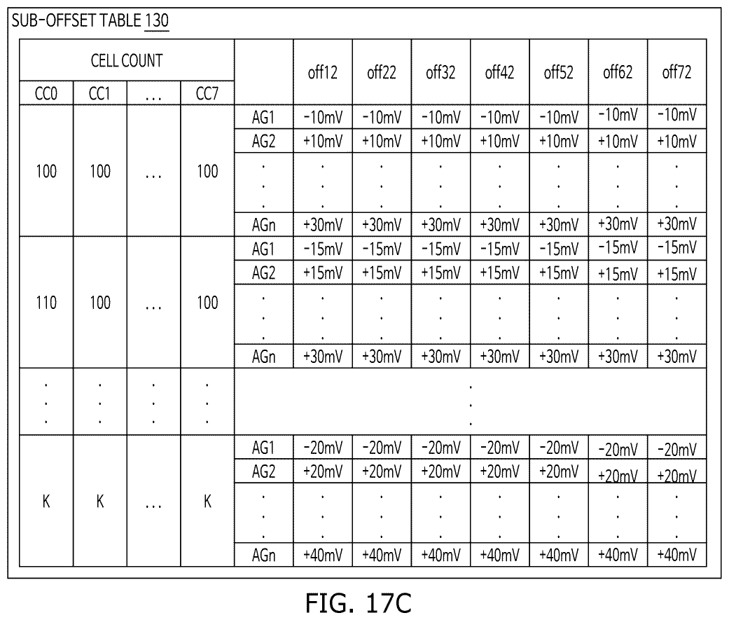

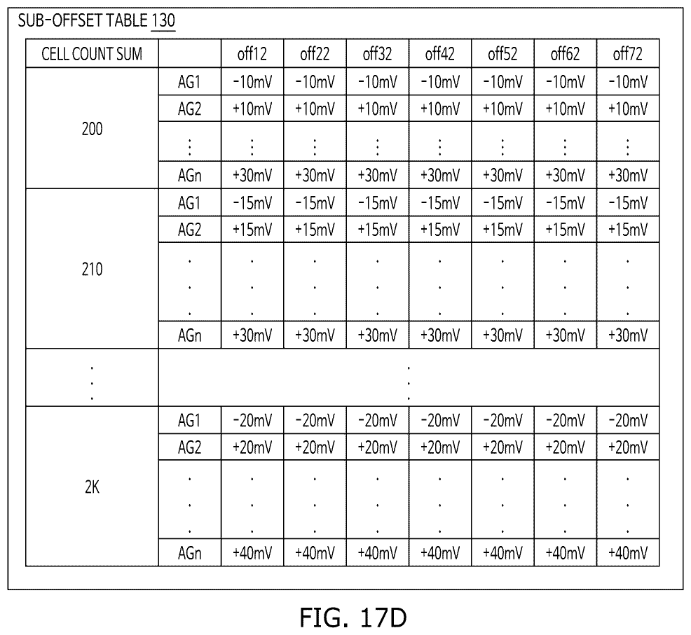

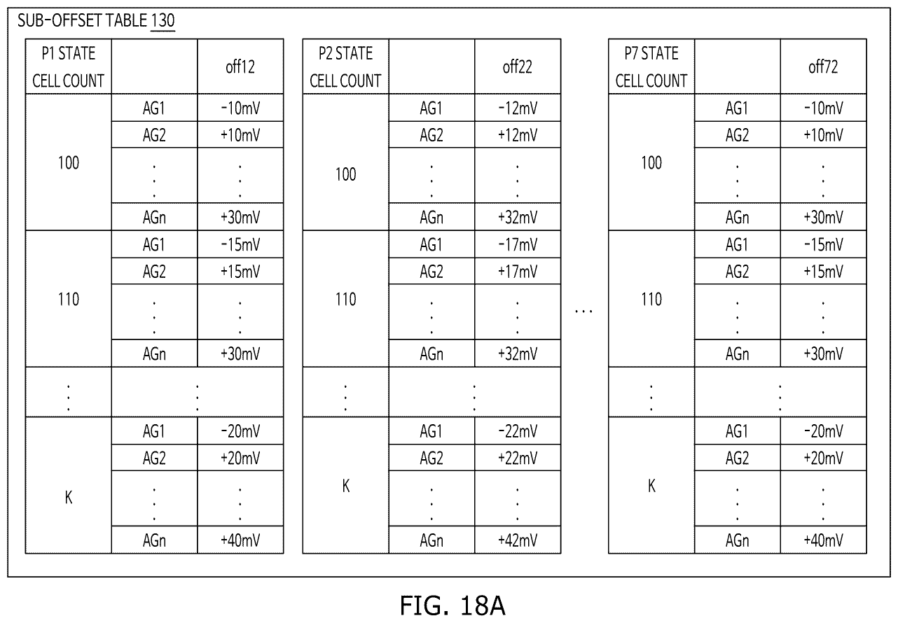

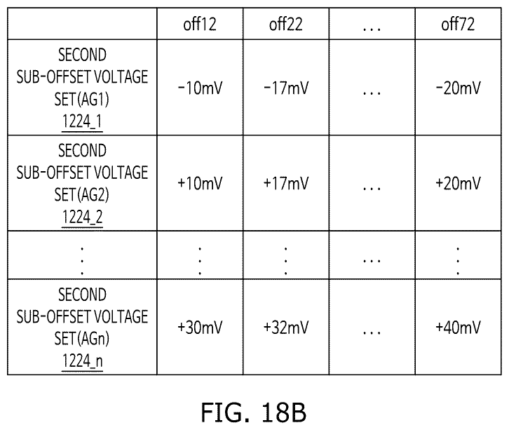

The storage controller 110 may determine or select second sub-offset voltage sets (e.g., 1224_1 to 1224_n) for the selected memory cells, from among a plurality of sub-offset voltage sets stored in the sub-offset table 130 based on the received number of selected memory cells, at S1350. This will be described in detail below with reference to FIGS. 17A to 18B. The storage controller 110 may transmit the determined second sub-offset voltage sets to the non-volatile memory 120, at S1360.

Alternatively, referring to FIGS. 1B and 13B, the non-volatile memory 120 may determine or select the second sub-offset voltage sets (e.g., 1224_1 to 1224_n) for the selected memory cells from among a plurality of sub-offset voltage sets stored in the sub-offset table 130, based on the number of selected memory cells that fall within a predetermined threshold voltage range in each of the one or more threshold voltage distributions, at S1350′.

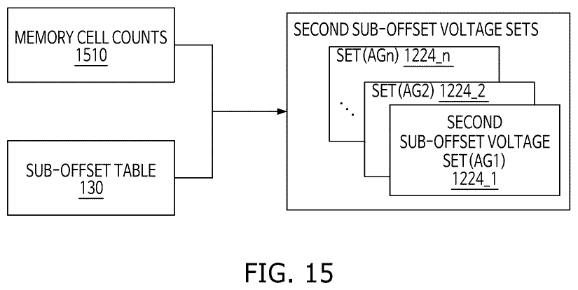

Specific aspects of determining the second sub-offset voltage sets (e.g., 1224_1 to 1224_n) will be described in detail below with reference to FIGS. 15 to 18B.

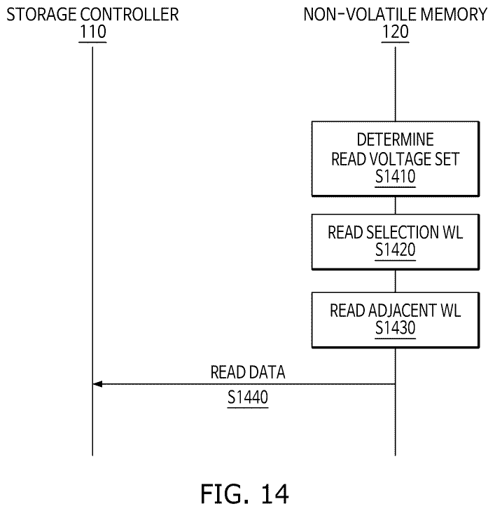

FIG. 14 is a flow diagram illustrating an example of generating and transmitting read data. The non-volatile memory 120 may determine a read voltage set (e.g., 1232 in FIG. 12A) including sub-read voltage sets (e.g., 1232_1 to 1232_n in FIG. 12A) based on the default voltage set, the first sub-offset voltage sets, and the second sub-offset voltage sets of FIGS. 13A and 13B, at S1410. For example, each of the sub-read voltage sets may be determined by the aspect described above with reference to FIG. 12C.

The non-volatile memory 120 may perform a read operation on the selected word line by using the determined read voltage set, at S1420. For example, the non-volatile memory 120 may perform a plurality of read operations on the selected memory cells of the selected word line using each of the sub-read voltage sets. By the plurality of read operations, a plurality of logic values may be sensed for each selected memory cell.

The non-volatile memory 120 may apply at least one group determination read voltage to the adjacent word line to perform a group determination read operation of the adjacent word line, at S1430. The group determination read operation may be performed by some implementations described above with reference to FIGS. 8A to 8C. By performing the group determination read operation of the adjacent word line, each of the adjacent memory cells in the adjacent word line may be classified as any one of a plurality of aggressor cell groups.

The non-volatile memory 120 may determine, among the plurality of logic values sensed for each selected memory cell, a logic value that corresponds to an aggressor cell group to which the adjacent memory cell adjacent to the corresponding selected memory cell is classified as data stored in the corresponding selected memory cell.

The non-volatile memory 120 may generate read data based on the data determined for each selected memory cell and transmit the read data to the storage controller 110, at S1440.

The present disclosure is not limited to the flow diagrams of FIGS. 13A to 14, and one or more steps of the process illustrated and described with reference to the flow diagrams of FIGS. 13A to 14 may be omitted, the order of each step may be changed, one or more steps may be performed overlapping each other in time, or one or more steps may be repeatedly performed several times.

FIG. 15 is a block diagram schematically illustrating a process of determining the second sub-offset voltage sets 1224_1 to 1224_n.

Referring to FIGS. 1A, 1B, and 15, the non-volatile memory 120 may count the number 1510 of selected memory cells that fall within a predetermined threshold voltage range in each of one or more threshold voltage distributions of the selected memory cells.

The counted number 1510 of selected memory cells will be described in detail below with reference to FIGS. 16A to 16C.

Based on the number 1510 of the selected memory cells, the second sub-offset voltage sets 1224_1 to 1224_n for the selected memory cells may be determined from among the plurality of sub-offset voltage sets stored in the sub-offset table 130. The sub-offset table 130 may be stored in the storage controller 110 or the non-volatile memory 120. Various aspects in which the second sub-offset voltage sets 1224_1 to 1224_n are determined using the sub-offset table 130 based on the number 1510 of selected memory cells will be described in detail below with reference to FIGS. 17A to 18B.

FIG. 16A is a diagram illustrating an example of a threshold voltage range in which the number of selected memory cells is counted. A first distribution 1610 represents threshold voltage distributions of non-degraded selected memory cells, and a second distribution 1620 represents threshold voltage distributions of degraded selected memory cells.

The number of selected memory cells (corresponding to 1510 of FIG. 15) may be counted within a predetermined threshold voltage range in a threshold voltage distribution corresponding to the state P7, among the states of the selected memory cells (e.g., E, P1 to P7), that has the highest average threshold voltage value and/or within a threshold voltage distribution corresponding to the erase state E. For example, referring to FIG. 16A, the number CC0 and CC7 of selected memory cells included in a first threshold voltage range rng0 in the first threshold voltage distribution corresponding to the erase state E and in an eighth threshold voltage range rng7 in the eighth threshold voltage distribution corresponding to the state P7 having the highest average threshold voltage value may be counted.

Comparing the first distribution 1610 with the second distribution 1620, it may be confirmed that the number of selected memory cells included in each of the first threshold voltage range rng0 and the eighth threshold voltage range rng7 before and after degradation of the selected memory cells changes. Therefore, the degree of degradation of the selected memory cells may be determined according to the degree of increase or decrease in the number of selected memory cells included in a specific threshold voltage range in the second distribution 1620 compared to the number of selected memory cells included in the same threshold voltage range in the first distribution 1610.

In sum, the number of selected memory cells included in a predetermined threshold voltage range varies according to the degree of degradation of the selected memory cells such that the correction amount of the read voltage (or sub-read voltage) of the selected memory cells may be determined in advance according to the number of selected memory cells included in the predetermined threshold voltage range and stored in the sub-offset table (e.g., 130 of FIG. 15). After calculating the number of selected memory cells included in a specific threshold voltage range, the calculated number of memory cells and information in the sub-offset table may be compared to determine second sub-offset voltages indicating a predetermined correction amount corresponding to the calculated number of memory cells.

This will be described below with reference to FIGS. 17A to 18B.

FIGS. 16B and 16C are diagrams illustrating an example of a threshold voltage range in which the number of selected memory cells is counted according to various aspects.

The number of selected memory cells that fall within a predetermined threshold voltage range may be counted in each of one or more threshold voltage distributions of the selected memory cells. The minimum threshold voltage or maximum threshold voltage of the threshold voltage range may be an optimal valley point at which two threshold voltage ranges intersect.

Referring to FIG. 16B, the number of selected memory cells CC6 and CC7 belonging to predetermined threshold voltage distributions rng6 and rng7 may be calculated from a plurality of threshold voltage distributions corresponding to a predetermined number (e.g., two) of program states (e.g., P6, P7) in the order of higher average threshold voltage value.

Referring to FIG. 16C, the number of selected memory cells CC0 to CC7 belonging to predetermined threshold voltage distributions rng0 to rng7 may be calculated from a plurality of threshold voltage distributions corresponding to all states (e.g., E, P1 to P7) of the selected memory cells.

FIGS. 17A to 17D are diagrams illustrating an example of the sub-offset table 130 according to various aspects, provided to explain a process of determining second sub-offset voltage sets.

In FIGS. 17A to 17D, second sub-offset voltage sets (e.g., 1224_1 to 1224_n of FIG. 15) corresponding to the aggressor cell groups AG1 to AGn may be determined based on the number of selected memory cells that fall within a predetermined threshold voltage range in each of one or more threshold voltage distributions of the selected memory cells.

Referring to FIGS. 16A and 17A, the second sub-offset voltage sets may be calculated based on the counted numbers CC0 and CC7 of selected memory cells in FIG. 16A. For example, if the counted numbers CC0 and CC7 of selected memory cells are 100 and 100, respectively, the second sub-offset voltages off12 to off72 for distinguishing the sub-states of the selected memory cells physically adjacent to the adjacent memory cells classified as the first aggressor cell group AG1 may be determined to be −10 mV. Likewise, the second sub-offset voltages off12 to off72 for distinguishing the sub-states of the selected memory cells physically adjacent to the adjacent memory cells classified as the second aggressor cell group AG2 may be determined to be +10 mV.

Referring to FIGS. 16B and 17B, the second sub-offset voltage sets may be calculated based on the counted numbers CC6 and CC7 of selected memory cells in FIG. 16B. For example, if the counted numbers CC6 and CC7 of selected memory cells are 110 and 100, respectively, the second sub-offset voltages off12 to off72 for distinguishing the sub-states of the selected memory cells physically adjacent to the adjacent memory cells classified as the first aggressor cell group AG1 may be determined to be −15 mV. Likewise, the second sub-offset voltages off12 to off72 for distinguishing the sub-states of the selected memory cells physically adjacent to the adjacent memory cells classified as the second aggressor cell group AG2 may be determined to be +15 mV.

Referring to FIGS. 16C and 17C, the second sub-offset voltage sets may be calculated based on the counted numbers CC0 to CC7 of selected memory cells in FIG. 16C. For example, if the counted numbers CC0 to CC7 of selected memory cells are 100, respectively, the second sub-offset voltages off12 to off72 for distinguishing the sub-states of the selected memory cells physically adjacent to the adjacent memory cells classified as the first aggressor cell group AG1 may be determined to be −10 mV. Likewise, the second sub-offset voltages off12 to off72 for distinguishing the sub-states of the selected memory cells physically adjacent to the adjacent memory cells classified as the second aggressor cell group AG2 may be determined to be +10 mV.

Referring to FIG. 17D, the second sub-offset voltages may be calculated based on a cell count sum of the number of selected memory cells that fall within a predetermined threshold voltage range in one or more threshold voltage distributions of the selected memory cells. For example, if the counted numbers CC0 and CC7 of selected memory cells in FIG. 16A are 100, respectively, the total is 200, and thus the second sub-offset voltages off12 to off72 for distinguishing the sub-states of the selected memory cells physically adjacent to the adjacent memory cells classified as the first aggressor cell group AG1 may be determined to be −10 mV. Likewise, the second sub-offset voltages off12 to off72 for distinguishing the sub-states of the selected memory cells physically adjacent to the adjacent memory cells classified as the second aggressor cell group AG2 may be determined to be +10 mV.

Alternatively, the second sub-offset voltages may be calculated based on a weighted sum of the number of selected memory cells that fall within a predetermined threshold voltage range in one or more threshold voltage distributions of the selected memory cells.

For example, if it is predetermined that an additional 10% weight is given to the number of selected memory cells that fall within a predetermined threshold voltage range of the first threshold voltage distribution, and if the counted numbers CC0 and CC7 of selected memory cells in FIG. 16A are 100, respectively, the weighted sum of the number of selected memory cells is 100*1.1+100=210, so the second sub-offset voltages off12 to off72 for distinguishing the sub-states of the selected memory cells physically adjacent to the adjacent memory cells classified as the first aggressor cell group AG1 may be determined to be −15 mV. Likewise, the second sub-offset voltages off12 to off72 for distinguishing the sub-states of the selected memory cells physically adjacent to the adjacent memory cells classified as the second aggressor cell group AG2 may be determined to be +15 mV.

In FIGS. 17A to 17D, it is illustrated that all of the second sub-offset voltages off12 to off72 are illustrated to be the same as each other, but the present disclosure is not limited thereto. For example, each of the second sub-offset voltages off12 to off72 may be different, or at least some of the second sub-offset voltages off12 to off72 may be different from some of the others. This is because the direction in which the threshold voltage distribution corresponding to each state is shifted and/or the degree of shift may be different for each state.

FIG. 18A is a diagram illustrating an example of the sub-offset table 130 according to other aspects, and FIG. 18B is a diagram illustrating an example of second sub-offset voltage sets determined based on the sub-offset table 130 of FIG. 18A.

Referring to FIG. 18A, the sub-offset table 130 may include a separate table provided for each of one or more program states P1 to P7. Each of the second sub-offset voltages off12 to off72 may be determined based on the number of selected memory cells that fall within a predetermined threshold voltage range in each of one or more threshold voltage distributions corresponding to the one or more program states P1 to P7.

For example, referring to FIGS. 16C, 18A, and 18B, if the counted numbers CC1, CC2, and CC7 of selected memory cells in the threshold voltage distribution corresponding to the states P1, P2, and P7 of FIG. 16C are 100, 110, and K, respectively (where, K is any natural number), the second sub-offset voltage sets 1224_1 to 1224_n may be determined as illustrated in the table illustrated in FIG. 18B.

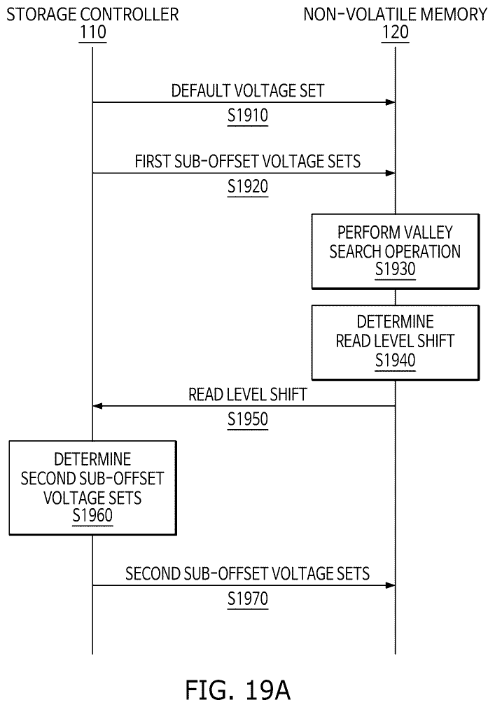

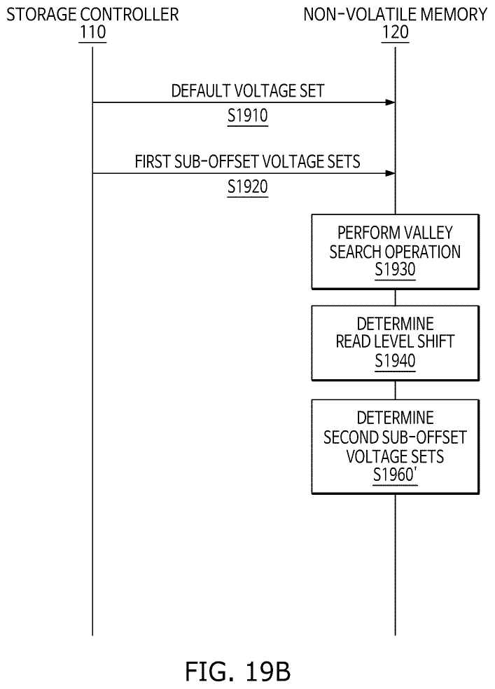

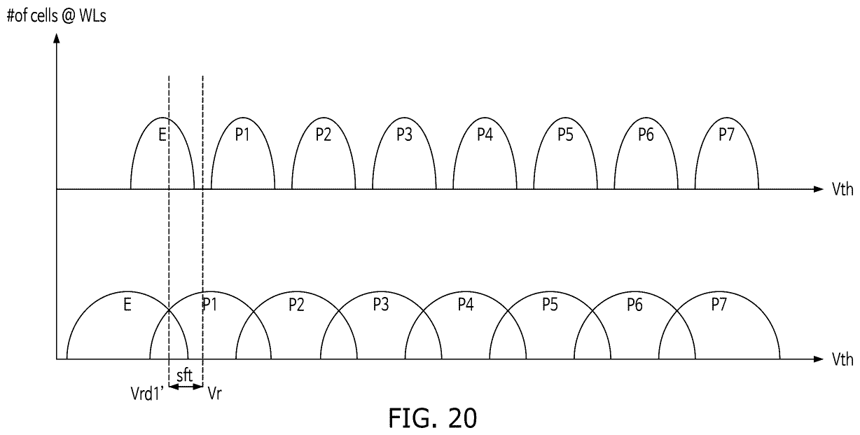

FIGS. 19A and 19B are diagrams illustrating a process of determining an offset according to some implementations, and FIG. 20 is a diagram illustrating an example of calculating a shift amount sft of a read voltage.

Steps S1910 and S1920 of FIGS. 19A and 19B correspond to steps S1310 and S1320 of FIGS. 13A and 13B, and overlapping descriptions thereof will be omitted below.

Referring to FIGS. 19A, 19B, and 20, the non-volatile memory 120 may perform a valley search operation on the selected memory cells, at S1930. The non-volatile memory 120 may compare the existing read voltage Vr (e.g., default read voltage or history read voltage) for distinguishing any two states E and P1 of the plurality of states E, P1 to P7 of the selected memory cells with a read voltage Vrd1′ corresponding to a valley between the two states E and P1 determined by performing the valley search operation at S1930 to determine a shift amount sft indicating a degree to which the read voltage is shifted, at S1940. In FIG. 20, the shift amount sft is determined only for the read voltage between the E state and the P1 state, but additionally or alternatively, the read voltage between other states (e.g., P1, P2) may be determined.

Referring to FIGS. 1A and 19A, the non-volatile memory 120 may transmit the shift amount of the read voltage between two states determined at S1940 to the storage controller 110, at S1950.

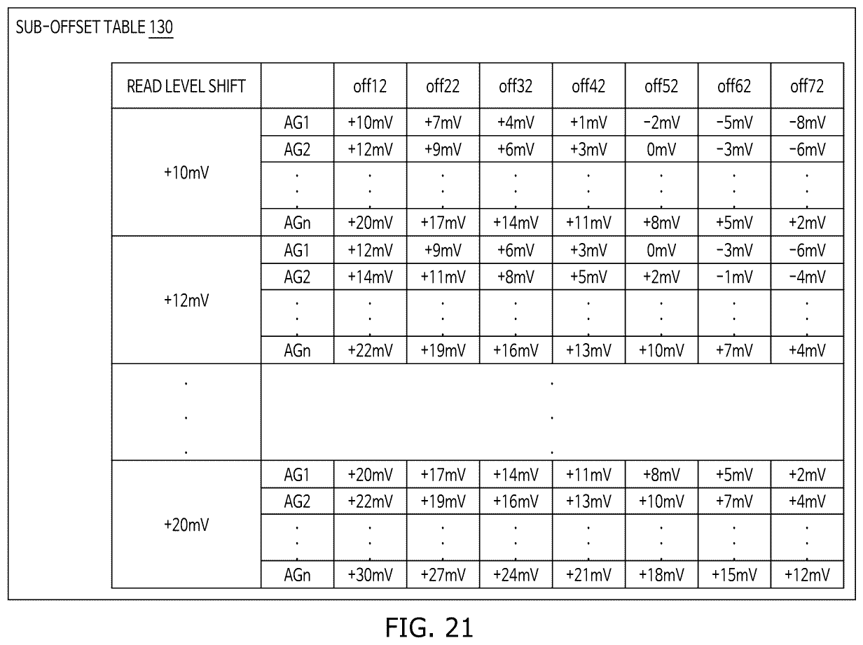

Based on the shift amount of the read voltage between two states, the storage controller 110 may determine or select the second sub-offset voltage sets (e.g., 1224_1 to 1224_n in FIG. 15) for the selected memory cells from among a plurality of sub-offset voltage sets stored in the sub-offset table 130, at S1960. This will be described in detail below with reference to FIG. 21. The storage controller 110 may transmit the determined second sub-offset voltage sets to the non-volatile memory 120, at S1970.

Alternatively, referring to FIGS. 1B and 19B, based on the shift amount of the read voltage between the two states, the non-volatile memory 120 may determine or select the second sub-offset voltage sets (e.g., 1224_1 to 1224_n in FIG. 15) for the selected memory cells from among a plurality of sub-offset voltage sets stored in the sub-offset table 130, at S1960′.

FIG. 21 is a diagram illustrating an example of the sub-offset table 130, provided to explain a process of determining second sub-offset voltage sets in FIGS. 19A and 19B.

Referring to FIG. 21, the second sub-offset voltage sets (e.g., 1224_1 to 1224_n in FIG. 15) corresponding to the aggressor cell groups AG1 to AGn may be determined based on the shift amount of the read voltage determined at S1940 of FIGS. 19A and 19B.

For example, if the shift amount of the read voltage determined at S1940 of FIGS. 19A and 19B is 10 mV, the second sub-offset voltages off12 to off72 for distinguishing the sub-states of the selected memory cells physically adjacent to the adjacent memory cells classified as the first aggressor cell group AG1 may be determined to be +10 mV, +7 mV, +4 mV, . . . , and −8 mV, respectively. Likewise, the second sub-offset voltages off12 to off72 for distinguishing the sub-states of the selected memory cells physically adjacent to the adjacent memory cells classified as the second aggressor cell group AG2 may be determined to be +12 mV, +9 mV, +6 mV, . . . , and −6 mV, respectively.

Example values of the number of selected memory cells, the sum of the number of selected memory cells, or the shift amount of the read voltage, which are illustrated in the sub-offset table 130 illustrated and described with reference to FIGS. 17A to 18A and 21, may indicate a specific range having the corresponding example value as one of the boundary values. In this case, the other boundary value of a specific range may be the example value that is next in order in the sub-offset table 130. For example, if the counted numbers CC0 and CC7 of selected memory cells in FIG. 17A are shown as 100 and 100, respectively, it may indicate an example in which the numbers CC0 and CC7 of selected memory cells are 100 or more but less than 110, and 100, respectively. In another example, the sum of the number (cell count sum) of selected memory cells shown as “200” in the sub-offset table 130 in FIG. 17D may indicate an example in which the sum of the number of selected memory cells is 200 or more but less than 210.

In the sub-offset table 130 illustrated and described with reference to FIGS. 17A to 18A and 21, the second sub-offset voltages corresponding to different aggressor cell groups are illustrated to be different from each other, but the present disclosure is not limited thereto. For example, the second sub-offset voltages corresponding to different aggressor cell groups may be the same as each other. That is, in this case, one second sub-offset voltage set may be used for a specific combination of the numbers of selected memory cells.

In the sub-offset table 130 illustrated and described with reference to FIGS. 17A to 18A and 21, the second sub-offset voltage sets corresponding to the number or the shift amount of selected memory cells set at regular intervals are illustrated, but the present disclosure is not limited thereto. For example, the sub-offset table 130 may include second sub-offset voltage sets corresponding to any possible combination of the number or the shift amount of selected memory cells. Alternatively, the second sub-offset voltage sets may be determined by a function using the number or the shift amount of selected memory cells as a variable, and the second sub-offset voltage sets may be determined in response to inputting a plurality of variables with any natural number values into the function. In this case, the table may illustrate any value of the values that a plurality of variables to be input to a corresponding function may have and the second sub-offset voltage set corresponding thereto.

Alternatively, if the number or the shift amount of selected memory cells included in a specific threshold voltage range does not correspond to the number or the shift amount specified in the table within the sub-offset table 130, the second sub-offset voltage sets corresponding to the nearest number or shift amount with the closest distance (e.g., Euclidean distance, Manhattan distance, Minkowski distance, Mahalanobis distance, etc.) within the table may be selected. For example, if the numbers CC0 and CC7 of selected memory cells in FIG. 16A are 102 and 102, respectively, the second sub-offset voltage sets corresponding to 100 and 100 that are a combination of the number in the sub-offset table 130 at the closest Euclidean distance or Manhattan distance in FIG. 17A may be selected.

Alternatively, after determining a regression model (e.g., multiple linear regression model, polynomial regression model, etc.) using the number or the shift amount specified in the table, the number or the shift amount of selected memory cells included in a specific threshold voltage range may be entered into the regression equation, or interpolation (e.g., linear interpolation, polynomial interpolation, spline interpolation, etc.) and/or extrapolation may be used to determine the second sub-offset voltage sets. For example, if the numbers CC0 and CC7 of selected memory cells in FIG. 16A are 105 and 100, respectively, the second sub-offset voltage sets may be determined based on the second sub-offset voltages corresponding to the number combination 100 and 100 and the number combination 110 and 100 in the sub-offset table 130 in FIG. 17A. In this case, the second sub-offset voltages off12 to off72 for distinguishing the sub-states of the selected memory cells physically adjacent to the adjacent memory cells classified as the first aggressor cell group AG1 may be determined to be −12.5 mV, which is an interpolation value of −10 mV and −15 mV. Likewise, the second sub-offset voltages off12 to off72 for distinguishing the sub-states of the selected memory cells physically adjacent to the adjacent memory cells classified as the second aggressor cell group AG2 may be determined to be +12.5 mV, which is an interpolation value of +10 mV and +15 mV.

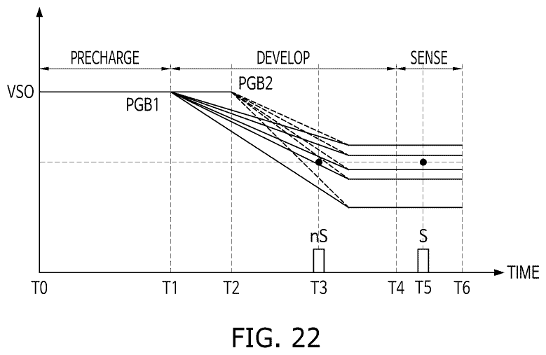

FIG. 22 is a diagram conceptually illustrating an example of calculating a cell count value. As illustrated in FIG. 22, an on-chip valley search operation for finding the optimal valley of states S1 and S2 (e.g., two adjacent states of E, P1 to P7 in FIG. 6) may be performed by a plurality of sensing operations. The plurality of sensing operations may be simultaneously performed in a plurality of page buffer circuits (e.g., 250 of FIG. 2).

Referring to FIG. 22, the on-chip valley search operation may be performed in a manner of sequentially latching sensing nodes at the same time points in different development periods in first page buffers PGB1 and second page buffers PGB2 and storing the sensing results. The first page buffers PGB1 and the second page buffers PGB2 may be included in the page buffer circuit.

A precharge operation may be performed from time T0 to time T1. For the precharge operation, a first bit line and a first sensing node connected to each of first page buffers PGB1 may be charged. If bit line set-up signals are activated, the sensing node and the first bit line may be precharged to a specific level. If a first bit line set-up signal is deactivated from a high level at time T1, the precharge circuit of each of the first page buffers PGB1 may be turned off. In addition, if a second bit line set-up signal is deactivated to a high level at time T2 after the time T1, the precharge circuit of each of second page buffers PGB2 may be turned off. At this time, the level of each sensing node of the first page buffers PGB1 and the level of each sensing node of the second page buffers PGB2 may vary according to the magnitude of the current flowing to the corresponding bit line according to whether the memory cell is turned on/off.

As illustrated in FIG. 22, each of the first page buffers PGB1 may precharge the sensing node from time T0 to time T1, and develop the first bit lines from time T1 to time T4. On the other hand, each of the second page buffers PGB2 may precharge the sensing node from time T0 to time T1, and may develop the second bit lines at time points later than time T1, that is, from time T2 to time T4.

The first sensing operation may include a latch reset nS sensing operation performed at time T3 and a latch set S sensing operation performed at time T5. A first cell count value may be calculated in the first page buffers PGB1 using an on-cell count value of the latch reset nS sensing operation and the latch set S sensing operation. In addition, a second cell count value may be calculated in the second page buffers PGB2 using an on-cell count value of the latch reset nS sensing operation and the latch set S sensing operation.

Through the operations described above with reference to FIG. 22, the cell count values described with reference to previous drawings may be calculated.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

It is obvious to those skilled in the art that the structure of the present disclosure may be variously modified or changed without departing from the scope or technical idea of the present disclosure. In view of the above description, if the modifications or changes of the present disclosure fall within the scope of the following claims and equivalents, the present disclosure is considered to include the changes and modifications of the present disclosure.

Example aspects have been disclosed in the drawings and the description above.

Although aspects have been described using specific terms in the present description, these terms are used only for the purpose of explaining the technical idea of the present disclosure and not to limit the meaning or the scope of the present disclosure described in the claims. Therefore, those with ordinary knowledge in the art will understand that various modifications and other equivalent aspects are possible. Therefore, the true technical protection scope of the present disclosure should be determined by the technical idea of the appended claims.

1. A storage device comprising:
a non-volatile memory device comprising:
a selected word line that connects to selected memory cells including first selected memory cells, and
an adjacent word line that connects to adjacent memory cells including first adjacent memory cells adjacent to the first selected memory cells; and
a storage controller configured to transmit, to the non-volatile memory device, a command instructing a data recovery read operation for the selected word line,
wherein the non-volatile memory device is configured to:
classify each of the adjacent memory cells into one of aggressor cell groups by applying at least one group determination read voltage to the adjacent word line;
generate, in response to receiving the command, read data for the selected word line based on a read voltage set, the read voltage set including a first sub-read voltage set for distinguishing first sub-states of the first selected memory cells; and
transmit the read data to the storage controller, and
wherein, based on the first adjacent memory cells being classified as a first aggressor cell group of the aggressor cell groups, the first sub-read voltage set is determined based on (i) a first coupling pattern by the first aggressor cell group and (ii) at least one of threshold voltage distributions associated with states of the selected memory cells.

2. The storage device according to claim 1, wherein
the adjacent memory cells comprise second adjacent memory cells,
the selected memory cells comprise second selected memory cells adjacent to the second adjacent memory cells,
the read voltage set comprises a second sub-read voltage set for distinguishing second sub-states of the second selected memory cells, and
based on the second adjacent memory cells being classified as a second aggressor cell group of the aggressor cell groups, the second sub-read voltage set is determined based on (i) a second coupling pattern by the second aggressor cell group and (ii) at least one of the threshold voltage distributions.

3. The storage device according to claim 2, wherein
the first sub-read voltage set comprises first sub-read voltages for distinguishing the first sub-states,
the second sub-read voltage set comprises second sub-read voltages for distinguishing the second sub-states,
the non-volatile memory device is further configured to:
perform a first read operation by application of the first sub-read voltages to the selected memory cells; and
perform a second read operation by application of the second sub-read voltages to the selected memory cells, and
the read data comprises data sensed in the first selected memory cells by the first read operation and data sensed in the second selected memory cells by the second read operation.

4. The storage device according to claim 1, wherein
the non-volatile memory device is configured to:
receive, from the storage controller, a default voltage set comprising default voltages for distinguishing states of the selected memory cells; and
determine, using the default voltage set and an offset voltage set comprising offset voltages for correcting the default voltages, the first sub-read voltage set.

5. The storage device according to claim 4, wherein
the offset voltage set comprises:
a first sub-offset voltage set comprising first sub-offset voltages corresponding to the first coupling pattern; and
a second sub-offset voltage set comprising second sub-offset voltages determined based on at least one of the threshold voltage distributions, and
the non-volatile memory device is configured to determine the offset voltages by adding each of the first sub-offset voltages and each of the second sub-offset voltages corresponding to each of the first sub-offset voltages.

6. The storage device according to claim 5, wherein
the states comprise an erase state or one or more program states, and
each of the second sub-offset voltages is determined based on a number of selected memory cells that fall within a threshold voltage range in each of one or more threshold voltage distributions corresponding to the one or more program states.

7. The storage device according to claim 5, wherein the second sub-offset voltage set is a sub-offset voltage set of a plurality of sub-offset voltage sets, and wherein the second sub-offset voltage set is selected based on a number of selected memory cells that fall within a predetermined threshold voltage range in each of one or more threshold voltage distributions.

8. The storage device according to claim 7, wherein the one or more threshold voltage distributions comprises, for the selected memory cells:
at least one of a threshold voltage distribution corresponding to a state having a highest average threshold voltage value among the states, or a threshold voltage distribution corresponding to an erase state;
a plurality of threshold voltage distributions corresponding to, among the states, a number of program states in an order of higher average threshold voltage value; or
a plurality of threshold voltage distributions corresponding to the states.

9. The storage device according to claim 7, wherein the second sub-offset voltage set is a sub-offset voltage set of the plurality of sub-offset voltage sets, and wherein the second sub-offset voltage set is selected based on a sum of a number of selected memory cells that fall within the predetermined threshold voltage range in the one or more threshold voltage distributions.

10. The storage device according to claim 7, wherein the second sub-offset voltage set is a sub-offset voltage set selected from among the plurality of sub-offset voltage sets based on a weighted sum of a number of selected memory cells that fall within the predetermined threshold voltage range in each of the one or more threshold voltage distributions.

11. The storage device according to claim 7, wherein the second sub-offset voltages are different voltages from each other.

12. The storage device according to claim 7, wherein the storage controller is configured to:
store the plurality of sub-offset voltage sets;
receive, from the non-volatile memory device, a number of selected memory cells that fall within the predetermined threshold voltage range in each of the one or more threshold voltage distributions;
select, based on the received number of selected memory cells, the second sub-offset voltage set, from among the plurality of sub-offset voltage sets; and
transmit the selected second sub-offset voltage set to the non-volatile memory device.

13. The storage device according to claim 7, wherein the non-volatile memory device is configured to:
store the plurality of sub-offset voltage sets; and
select the second sub-offset voltage set from among the plurality of sub-offset voltage sets, based on the number of selected memory cells that fall within the predetermined threshold voltage range in each of the one or more threshold voltage distributions.

14. The storage device according to claim 5, wherein
the storage controller is configured to:
store a plurality of sub-offset voltage sets that comprise the first sub-offset voltage set and correspond to the aggressor cell groups; and
transmit the plurality of stored sub-offset voltage sets to the non-volatile memory device, and
the non-volatile memory device is configured to select, based on the first adjacent memory cells being classified as a first aggressor cell group of the aggressor cell groups, the first sub-offset voltage set as a part of the offset voltage set.

15. The storage device according to claim 1, wherein
the storage controller is configured to provide the non-volatile memory device with a control signal instructing application of at least one group determination read voltage to the adjacent word line, and an adjacent address, and
the non-volatile memory device is configured to compare threshold voltages of the first adjacent memory cells with the at least one group determination read voltage to classify the first adjacent memory cells into the first aggressor cell group.

16. The storage device according to claim 1, wherein the storage controller comprises an error correction code (ECC) circuit, and is configured to transmit, in response to an occurrence of uncorrectable ECC (UECC) data after correcting the data read from the selected word line by the ECC circuit, the command to the non-volatile memory device.

17. A non-volatile memory device comprising:
a voltage generator;
a control logic circuit;
an adjacent word line comprising first adjacent memory cells and second adjacent memory cells; and
a selected word line comprising first selected memory cells adjacent to the first adjacent memory cells and second selected memory cells adjacent to the second adjacent memory cells,
wherein the control logic circuit is configured to:
control the voltage generator to apply at least one group determination read voltage to the adjacent word line and classify each of the adjacent memory cells into one of aggressor cell groups;
control the voltage generator, in response to receiving a command instructing a data recovery read operation for the selected word line, to apply first sub-read voltages for distinguishing first sub-states of the first selected memory cells to selected memory cells and to perform a first read operation; and
control the voltage generator, in response to receiving the command, to apply second sub-read voltages for distinguishing second sub-states of the second selected memory cells to the selected memory cells and to perform a second read operation,
wherein, based on the first adjacent memory cells being classified as a first aggressor cell group of the aggressor cell groups, the first sub-read voltages are determined based on (i) at least one of threshold voltage distributions associated with states of the selected memory cells and (ii) a first coupling pattern by the first aggressor cell group, and
wherein, based on the second adjacent memory cells being classified as a second aggressor cell group of the aggressor cell groups, the second sub-read voltages are determined based on (i) at least one of the threshold voltage distributions and (ii) a second coupling pattern by the second aggressor cell group.

18. An operating method of a storage device comprising a storage controller and a non-volatile memory device, the method comprising:
transmitting, by the storage controller, to the non-volatile memory device, a command instructing a data recovery read operation for a selected word line to which selected memory cells are connected, the selected memory cells comprising one or more selected memory cells adjacent to one or more adjacent memory cells included in an adjacent word line;
applying, by the non-volatile memory device, at least one group determination read voltage to the adjacent word line and classifying each of the adjacent memory cells into any one of aggressor cell groups;
determining, by the storage device, a sub-read voltage set for distinguishing sub-states of the one or more selected memory cells; and
in response to receiving the command, generating, by the non-volatile memory device, read data for the selected word line based on a read voltage set comprising the determined sub-read voltage set and transmitting the read data to the storage controller, wherein,
based on the one or more adjacent memory cells being classified into a specific aggressor cell group of the aggressor cell groups, the sub-read voltage set is determined based on a coupling pattern by the specific aggressor cell group, and at least one of threshold voltage distributions associated with states of the selected memory cells.

19. The operating method according to claim 18, wherein determining the sub-read voltage set comprises:
receiving, by the non-volatile memory device, a default voltage set comprising default voltages for distinguishing the states of the selected memory cells, and a first sub-offset voltage set comprising first sub-offset voltages corresponding to the coupling pattern from the storage controller;
receiving, by the storage controller, a number of selected memory cells that fall within a threshold voltage range from each of one or more threshold voltage distributions of the threshold voltage distributions from the non-volatile memory device;
selecting, by the storage controller, a second sub-offset voltage set from among a plurality of sub-offset voltage sets pre-stored in the storage controller based on the received number of the selected memory cells;
transmitting, by the storage controller, the selected second sub-offset voltage set to the non-volatile memory device; and
determining, by the non-volatile memory device, the sub-read voltage sets using the default voltage set, the first sub-offset voltage set, and the second sub-offset voltage set.

20. The operating method according to claim 18, wherein determining the sub-read voltage set comprises, by the non-volatile memory device:
receiving, from the storage controller, a default voltage set comprising default voltages for distinguishing the states of the selected memory cells and a first sub-offset voltage set comprising first sub-offset voltages corresponding to the coupling pattern;
selecting a second sub-offset voltage set from among a plurality of sub-offset voltage sets pre-stored in the non-volatile memory device, based on a number of selected memory cells that fall within a threshold voltage range in each of one or more threshold voltage distributions; and
determining the sub-read voltage sets using the default voltage set, the first sub-offset voltage set, and the second sub-offset voltage set.
